(19) United States
(12) Patent Application Publication
(10) Pub. No.: US 2014/0305479 A1
(43) Pub. Date: Oct. 16, 2014

(54) Thermoelectric devices having reduced parasitics

(71) Applicants: David Charles Nemir, El Paso, TX (US); Edward Rubio, Santa Teresa, NM (US); Jan Bastian Beck, EL Paso, TX (US)

(72) Inventors: David Charles Nemir, El Paso, TX (US); Edward Rubio, Santa Teresa, NM (US); Jan Bastian Beck, EL Paso, TX (US)

(21) Appl. No.: 13/986,183

(22) Filed: Apr. 10, 2013

(51) Int. Cl. H01L 35/32; H01L 35/34

(52) U.S. Cl. CPC H01L 35/325; H01L 35/34
USPC 136/203; 136/224; 136/205; 438/54; 136/201

(57) ABSTRACT

A tubular thermoelectric device wherein conductive substrates and completion elements serve a multiple role of structural support, thermal conductance and electrical conductance. Improved system thermoelectric performance accrues from the minimization of the number of interfaces between dissimilar materials, leading to a reduction in system thermal parasitics and system electrical parasitics. By engineering the shape and orientation of substrates and completion elements, improvements in heat transfer to heat reservoirs is accomplished and improved electrical conductivity is accomplished.

### CROSS-REFERENCE TO RELATED APPLICATIONS

This application is a continuation-in-part application of U.S. patent application Ser. No. 12/653,721 entitled “Thin walled thermoelectric devices and methods for production thereof” which was filed on Dec. 17, 2009 and which claims the priority date of U.S. Provisional Patent Application Ser. No. 61/138,574 which was filed on Dec. 18, 2008. This application further claims the priority of U.S. Provisional Patent Application 61/624,509 filed Apr. 16, 2012, which is incorporated by reference as if written herein in its entirety.

### BACKGROUND OF THE INVENTION

1. Field of the Invention

This invention relates to thermoelectric devices and methods for building such devices to reduce thermal and electrical parasitic influences and thereby improve system performance.

2. Background of the Invention

Thermoelectric phenomena arise out of the intercoupled electrical and thermal currents in a conductor or semiconductor material. A thermoelectric generator may be viewed as a mechanism for energy conversion, transforming energy in one form (heat) into another form (electricity). A thermoelectric heat pump, also known as a Peltier cooler, is an energy conversion technique in which electrical energy is used to transfer heat from one location to another. Both thermoelectric generators and thermoelectric heat pumps have similar construction and their performance is affected by similar factors.

The key component of a thermoelectric device is the thermoelement, which is the active portion that does the actual conversion. Although thermoelements may be built using conductors such as iron and nickel, higher efficiency thermoelements are built using certain types of semiconductors. There are two general categories of thermoelectric material, classified according to the majority charge carrier. In n-type thermoelements, the majority charge carriers are electrons. In p-type thermoelements, the majority charge carriers are holes. Thermoelectric devices are generally formed by connecting a number of n-type and p-type (equivalently N-type and P-type) thermoelements in electrical series and in thermal parallel.

The heat source for a thermoelectric generator is often referred to as the heat reservoir, having an ability to deliver any arbitrary amount of heat energy at a constant “hot” temperature. The heat sink for a thermoelectric generator is often referred to as a cold reservoir, having the ability to absorb any arbitrary amount of heat energy at a constant “cold” temperature. We note that the terms “hot” and “cold” are relative terms and are used to express temperature potentials. Also, although the heat source and heat sink are modeled as constant temperature reservoirs with the ability to deliver/absorb any amount of thermal energy, in real systems there will be thermal resistances that limit the amount of heat flow. In a thermoelectric generator, heat energy flows from hot to cold through the active thermoelements. In a thermoelectric heat pump, heat energy flows from cold to hot through the active thermoelements.

Thermoelectric generation takes place when a temperature difference is applied to the thermoelements, causing mobile charge carriers, either electrons or holes, to migrate from hot to cold. The resulting separation of charge creates an electric potential known as the Seebeck voltage, that is given by ΔV=SΔT, where S is a temperature dependent material property known as the thermopower or Seebeck coefficient, and, by convention, ΔT represents the temperature of the cold side with respect to the hot side. The thermopower for a material may be positive or negative depending upon the type of majority charge carrier.

Besides the thermopower, two other material parameters of interest when analyzing a thermoelectric material are the electrical conductivity, σ, and the thermal conductivity, κ, and are important when analyzing losses in a thermoelectric device. Losses due to Joule (I²R) heating within the active thermoelectric element are minimized when the thermoelements have a high electrical conductivity. In a generator, thermal energy losses which are due to thermal energy that passes all the way through the thermoelectric element as a “thermal leak”, without being converted to electricity, can be minimized by having a low thermal conductivity. In a heat pump, thermal energy losses are in a direction that oppose the direction of active heat transport, reducing the effectiveness of the heat pumping. As with a generator, the heat losses in a heat pump can be reduced by having a low thermal conductivity. Thermal conductivity may be broadly partitioned into two components. First, there is the electronic component of thermal conductivity which represents the portion of heat transfer that accompanies the movement of electrons through a thermoelectric material. Second, there is the portion of heat transfer that is due to quanta of lattice vibrations, also known as phonons. Good electrical conductivity is a desirable quantity for a thermoelectric material, so the portion of thermal conductivity that is due to electronic heat transfer cannot be avoided. However, in a thermoelectric material, the portion of thermal conductivity that is due to phonons may be reduced through techniques that restrict phonon transport without adversely impacting electron flow.

The key material properties governing thermoelectric performance are often lumped into a single thermoelectric figure of merit Z, where

$$Z = \frac{σ {S}^{2}}{{κ}_{e} + {κ}_{L}} , \qquad ( 1 )$$

and κₑ and κ_{L} are, respectively, the electronic and the lattice thermal conductivities and their sum is the total thermal conductivity, κ. The parameters σ, S, and κ are temperature dependent and so Z is also a function of temperature. Higher values of Z give higher thermoelectric conversion efficiencies. However, for practical generators, the amount of power that can be generated from a given hot and cold reservoir will also depend upon the ability of the hot and cold reservoirs to, respectively, deliver thermal energy to the thermoelectric generator and absorb thermal energy from the thermoelectric generator. In particular, there will be a number of thermal interfaces separating the two “ideal” reservoirs from the active thermoelectric material. These result in thermal resistances, across which there may be significant temperature drops, leading to a diminished temperature gradient across the thermoelement and thus reduced power generating capability. In a generator the temperature drops across the interfaces that lie between the ideal reservoirs and the thermoelectric material are parasitic in the sense that they serve to detract from the temperature gradient that appears across the thermoelement and thus reduce the magnitude of the generated voltage. In a similar way, in a heat pump, temperature drops across the interfaces between the thermoelements and the reservoirs reduces the amount of heat that can be moved between reservoirs for a given amount of power.

The identification of Z as a figure-of-merit for thermoelectric materials originally arose out of a derivation for thermoelectric efficiency in a generator, that is, the maximum amount of electrical energy that can be obtained in a thermoelectric generator from a given amount of thermal energy. Subject to certain assumptions, the maximum efficiency will always increase with increasing Z according to the formula:

$${η}_{max} = \frac{Δ T}{{T}_{h}} \times \frac{\sqrt{1 + ZT} - 1}{\sqrt{1 + ZT} + \frac{{T}_{c}}{{T}_{h}}} \qquad ( 2 )$$

where ηₘₐₓ is the maximum efficiency, Tₕ is the hot side temperature, T_{c} is the cold side temperature, T is the average temperature (Tₕ+T_{c})/2, and ΔT=Tₕ−T_{c}. Of particular note is the first term on the right in equation (2), which is an expression for the Carnot limit, which is the maximum theoretical efficiency with which thermal energy can be converted to work. Also of note is that Z is the only material dependent term in the calculation for thermoelectric efficiency. From the standpoint of thermoelectric conversion efficiency, for any given configuration of thermoelectric elements, the key parameter of interest is the value of Z. For thermoelements that are constructed from a state-of-the-art material like doped alloys of bismuth-telluride, with a Z of approximately 0.003° K⁻¹, and a temperature across the thermoelectric of 400° K (hot side) to 300° K (cold side), the maximum efficiency by equation (2) is approximately 4.8%. It should be noted that every time that Z appears in equation (2), it is multiplied by the average temperature T. For this reason, the product ZT is often used in place of Z to describe the thermoelectric quality of a material. ZT is dimensionless.

Conversion efficiency is not necessarily the most important criterion for a power generator, an idea that is illustrated by the well known example from electrical networks theory of a resistive load, R_{L}, attached to a Thevenin source model consisting of an ideal voltage source, V_{OC}, in series with a source resistance, Rₛ. The equations for generated power and efficiency are, respectively,

$${P}_{RL} = \frac{{V}_{OC}^{2} {R}_{L}}{{( {R}_{L} + {R}_{S} )}^{2}} , \\ and \\ η = \frac{{R}_{L}}{{R}_{L} + {R}_{S}} . \qquad ( 3 )$$

The maximum power transfer to the load is calculated to occur when the load resistance has the same value as the source resistance, that is, R_{L}=R_{S}, and corresponds to a power transfer efficiency of 50%. The efficiency increases as the load resistance is increased, but the amount of power transfer is reduced. For very high load resistances, the efficiency approaches 100%, but the power transfer tends to zero. For any given V_{OC} and load R_{L}, both power and efficiency can be increased by reducing R_{S}. In this example, R_{S} may be considered to be a loss component or equivalently, an electrical parasitic. Any voltage drop across R_{S} is a reduction in the voltage across R_{L} and thus a reduction in the electrical power delivered to R_{L}. A thermoelectric generator is far more complicated than the simple electrical generator described above since there are intercoupled thermal and electrical currents. However, there are two important points from this example that will carry over to thermoelectric generation. First, designing for maximum power is different from designing for maximum efficiency. Second, from equation (3) we see that for any given load and given voltage source, we can simultaneously increase both power and efficiency by decreasing the parasitic loss component, in this case, R_{S}. This second point is key. Reducing parasitics in a generator increases BOTH power AND efficiency!

Thermoelectric devices are constructed from the interconnection of the active thermoelements with nonactive (nongenerating/non heat pumping) elements that provide structural support, electrical interconnection and thermal/electrical insulation. The nonactive elements are necessary for building a system of interconnected thermoelectric elements, however, they contribute parasitic electrical and thermal resistances that are a detriment to both power generation and to heat pumping.

When describing a thermoelectric material, the advantage of characterizing the material by the Z, or equivalently, the ZT, is that it is a single convenient metric against which different candidate thermoelectric materials may be measured. However, an exclusive reliance on Z to express thermoelectric quality can be misleading. When a thermoelectric material is used in a system, system parasitics can dominate in determining overall device (system) performance. These parasitics may be broadly partitioned into thermal resistances and electrical resistances and both detract from system level power generation and system level heat pumping. From a generation standpoint, thermal parasitics are components that introduce temperature drops, resulting in a reduction of the ΔT across the active thermoelements. Electrical parasitics represent voltage drops, reducing the amount of voltage that is delivered to an electrical load. It is always desirable to reduce the thermal and electrical parasitics in a thermoelectric device. There will generally be a trade-off between the influences of these two parasitics—for example, often the influence of electrical parasitics can only be reduced at the cost of increasing thermal parasitics, or vice versa, and, depending upon the overall system topology, this can actually favor one thermoelectric material over another, even if both have the same Z. When system efficiency is the dominant concern, this might even favor the selection of a lower Z material in choosing between two candidates. The topologies described in the present invention can result in reductions of both electrical and thermal parasitics and this is advantages from a systems standpoint, regardless of the chosen thermoelectric material.

One tool in reducing thermal and electrical parasitics in a thermoelectric device is to utilize spraycoating for device manufacture. A technique that is also referred to as thermal spray or spraycasting, spraycoating is a generic name for a category of manufacturing techniques that use a combination of heat and spray velocity to apply a coating onto a substrate. The starting point is a powdered feedstock that may be (but is not necessarily) increased in temperature in order to partially or completely melt the powder particles. The powder particles are accelerated at a high velocity and then impacted against a substrate, where they fuse to implement a dense, uniform coating as the kinetic energy in the high velocity particles results in plasticly deformed “splats” when the particles come to rest. By using spraycoating to adhere thermoelectric material to electrical conductors, good electrical and mechanical bonds can be obtained that reduce parasitic contact resistance. In particular, spraycoating represents a high volume manufacturing process that can be used to apply thermoelectric generation structures onto heat exchanger members that are interposed between a hot fluid and a cold fluid.

Heat exchangers are ubiquitous in power generation and industrial plants and are designed for the optimal transfer of heat energy from one reservoir to another reservoir. Some examples are boilers (where the heat from combustion gases on one side is transferred to the other side to boil water or to heat steam), and recuperators, which use exhaust heat (hot side) to preheat incoming combustion air (cold side). Other types of heat exchangers are condensers and ventilated radiators. By deploying thermoelectric technology in the wall of a heat exchanger, disposed between the hot and the cold sides, it is possible to have electric generation occurring as a byproduct of heat exchange.

3. Description of the Related Art

U.S. Pat. No. 6,127,766 (Roidt) describes a paired tube bank where a first tube element is constructed using an n-type of thermoelectric material applied to an inner conductive tube and is then covered by an outer conductive tube, and a separate second tube element is constructed in a similar way using p-type thermoelectric material. The use of single element tubes results in significant power loss due to parasitic electrical resistance.

U.S. Pat. No. 6,096,966 (Nishimoto et al) discloses the fabrication of thermoelectric modules requiring an electrically insulating outer layer and being fabricated of either n-type thermoelectric material or of p-type thermoelectric material. U.S. Pat. No. 7,868,242 B2 (Takahashi) discloses a thermoelectric conversion module having a plurality of thermoelectric elements of a single type, either n-type or p-type, that are covered with electrodes and disposed between inner and outer tubes that are electrically insulated. When insulation is a requisite part of a design and is interposed between thermal reservoirs and the active thermoelements, it represents thermal resistance (thermal parasitics) which will reduce power generation capability. Furthermore, in U.S. Pat. No. 7,868,242 B2 (Takahashi) the connecting member that is needed between elements connects between the electrode at the inner surface of the outer tube to the electrode at the outer surface of the inner tube and acts as a thermal “leak” that bypasses the thermoelements. If this connecting member is chosen to have small cross-section to minimize heat transfer, then it will have relatively large electrical resistance and result in large electrical parasitic losses.

The present invention addresses the issues of electrical and thermal parasitics and presents practical thermoelectric device designs based on simple elements that address the limitations of prior art designs and have the following objects and advantages:
1) parasitic temperature drops between heat reservoir to thermoelements and between thermoelements to cold reservoirs are reduced;
2) parasitic electrical resistive losses are reduced;
3) there is a reduction of the number of interfaces between thermal reservoirs and thermoelements;
4) it lends itself to incorporation into a heat exchanger as part of the wall between thermal reservoirs, thereby producing electrical energy as a byproduct of heat exchange;
5) reduced thermal and electrical parasitics yields improved performance for both thermoelectric generation and thermoelectric heat pumping applications;
6) the approach lends itself to the large scale production of a variety of thermoelectric devices through the interconnection of only a few basic subcomponents; and
7) it combines the best features of the pi and Oersted topologies.

Other objects and advantages will be apparent from the detailed drawings and description to follow.

### BRIEF DESCRIPTION OF THE DRAWINGS

FIG. 1 depicts a four element pi configuration thermoelectric generator.

FIG. 2 depicts a pi and an Oersted thermoelectric device topology.

FIG. 3 depicts an exploded view of a single leg in a pi topology.

FIG. 4 depicts a model used for simulating power generation as a function of thermoelectric pellet dimensions.

FIG. 5 depicts plots of maximum generated powder and corresponding efficiency as functions of thermoelectric thickness L₁ and generator leg length L₂.

FIG. 6 depicts a detailed plot of maximum generated power as a function of thermoelectric pellet length for various thermoelectric pellet thicknesses and illustrating the slope that impacts choice of thermoelectric length

FIG. 7 depicts plots of maximum generated power as a function of L₁ and L₂ for conductor thicknesses L₃=0.1 mm, 0.2 mm, 0.4 mm and 0.8 mm.

FIG. 8 depicts a region of a pi configured thermoelectric generator that contributes electrical resistance and thereby detracts from generation.

FIG. 9 depicts a region of a pi configured thermoelectric generator in which no generation takes place and which further can serve as a thermal “leak”.

FIG. 10 depicts the temperature profile in the vicinity of a wall between two fluids of differing temperatures.

FIG. 11 depicts a lumped thermal model for a heat exchanger wall

FIG. 12 depicts a thermoelectric tublet

FIG. 13 depicts the attachment of a conductive sleeve to two tublets to complete a pi configured thermoelectric device

FIG. 14 depicts optional embodiments for the insulator between adjoining tublets

FIG. 15 depicts a complete tubular thermoelectric generator having six thermoelements

FIG. 16 depicts a cross-sectional view of a tubular thermoelectric generator depicting fins on the inside tube and fins on the outside sleeve

FIG. 17 depicts a shell and tube heat exchanger

FIG. 18 depicts a flat plat thermoelectric building block

FIG. 19 depicts the completion of a thermoelectric circuit using flat plate design

FIG. 20 shows side views of a flat plate thermoelectric generator using rectangular cross-sectioned plates and optional non-rectangular attachment between thermoelements

FIG. 21 shows a tubular thermoelectric generator/heat pump which is formed by connecting long flat plate segments in a fanfold arrangement

### LIST OF REFERENCE NUMERALS

10—n type thermoelement
12—p type thermoelement
14—Top electrical conductor
16—Bottom electrical conductor
18—Electrical wire
20—Electrical load
22—Electrical current
23—Heat energy flux sourced from heat source
24—Heat energy flux delivered to heat sink
26—Hot paddle
28—Cold paddle
29—Single leg in a pi connected topology
30—Thermoelectric pellet/thermoelement
31—Conductor overhang between pellets
32—Top conductor
34—Bottom conductor
36—Cross section of thermoelement in direction normal to heat energy flux
38—Cross-section of top conductor normal to direction of flow of electrical current
40—Line of constant hot temperature
42—Line of constant cold temperature
44—Topside thermal resistance
46—Bottomside thermal resistance
48—Top conductor
50—Bottom conductor
52—Electrical load
54—Thermoelectric pellet
58—Curve for thermoelectric thickness L₁=0.5 mm
60—Curve for thermoelectric thickness L₁=1 mm
62—Curve for thermoelectric thickness L₁=2 mm
64—Curve for thermoelectric thickness L1=4 mm
66—Curve for thermoelectric thickness L₁=8 mm
68—Slope of maximum change of power with thermoelectric length L₂
70—Maximum power as function of L1, L2 when L3=0.1 mm
72—Maximum power as function of L1, L2 when L3=0.2 mm
74—Maximum power as function of L1, L2 when L3=0.4 mm
76—Maximum power as function of L1, L2 when L3=0.8 mm
78—Electrical attachment between adjacent legs
80—Region of non-generation
82—Nonactive length between adjacent thermoelectric legs
84—Active length of thermoelectric leg
86—Top conductor
88—Bottom conductor
90—Thermoelectric element
92—Interface between thermoelement and conductor
94—Heat exchanger wall
96—Hot fluid
98—Cold fluid
100—Curve of temperature as a function of position relative to the heat exchanger wall
102—Axis indicating temperature
104—Axis indicating displacement normal to the heat exchanger wall
106—Node of hot temperature, T_{H}
108—Thermal resistance between T_{H} and wall
110—Hot side wall of heat exchanger
112—Thermal resistance of wall of heat exchanger
114—Cold side wall of heat exchanger
116—Thermal resistance between cold side of wall and T_{C}
118—Node of cold temperature, T_{C}
119—Short tube
120—Outer diameter of tube
121—Tube length
122—n-type thermoelectric coating
124—p-type thermoelectric coating
126—Thickness of thermoelectric coatings
128—Length of thermoelements
130—Gap between adjacent thermoelements
132—Gap between thermoelectric coating and edge of tube
134—Tube 1
136—Tube 2
138—n-type thermoelectric coating
140—p-type thermoelectric coating
142—n-type thermoelectric coating
144—p-type thermoelectric coating
146—Sleeve
148—Insulator
149—Insulator sleeve with blades
150—Blades
151—Insulator sleeve with pegs
153—Pegs
154—Conductive end attachment collar
155—Conductive end attachment collar
156—Electrical wire
157—Electrical wire
158—Conductive sleeve
159—Conductive sleeve
160—n-type thermoelectric coating
162—p-type thermoelectric coating
164—n-type thermoelectric coating
166—p-type thermoelectric coating
168—n-type thermoelectric coating
170—p-type thermoelectric coating
172—Insulator
174—Insulator
176—Conductive inner tube with internal fins
178—Conductive inner tube with internal fins
180—Conductive inner tube with internal fins
182—Outer sleeve with fins
184—Outer fin
186—Thermoelectric material
188—Inner tube with fins
190—Inner fin
192—Shell
194—Thermoelectric generation tube
196—Tube inlet
198—Tube outlet
200—Inlet plenum
202—Outlet plenum
204—Tube sheet
206—Shell inlet
208—Shell outlet
210—N-type thermoelectric layer
212—P-type thermoelectric layer
214—Electrically and thermally conductive flat substrate
216—Thermoelement length L₂
218—The L₄ dimension perpendicular to both heat energy flux and electrical current flow.
220—Bottom substrate
221—Left top substrate
222—Middle top substrate
224—Right top substrate
226—Electrical connection
228—Electrical conductors
230—Electrical load
232—Top electrical conductor
234—Bottom electrical conductor
236—N-type thermoelectric material
238—P-type thermoelectric material
240—Gap between thermoelements
242—Top conductor with rectangular cross-section
244—Bottom conductor designed to reduce thermal and electrical parasitics
246—Outside conductor
248—Inside conductor
250—P-type thermoelement
252—N-type thermoelement
254—End conductor
256—End conductor
258—Insulating seal to complete tube
260—Electrical connection
262—Electrical connection
264—Length of tube

### DESCRIPTION OF THE PREFERRED EMBODIMENTS

In the following paragraphs, the present invention will be described in detail through examples and detailed drawings.

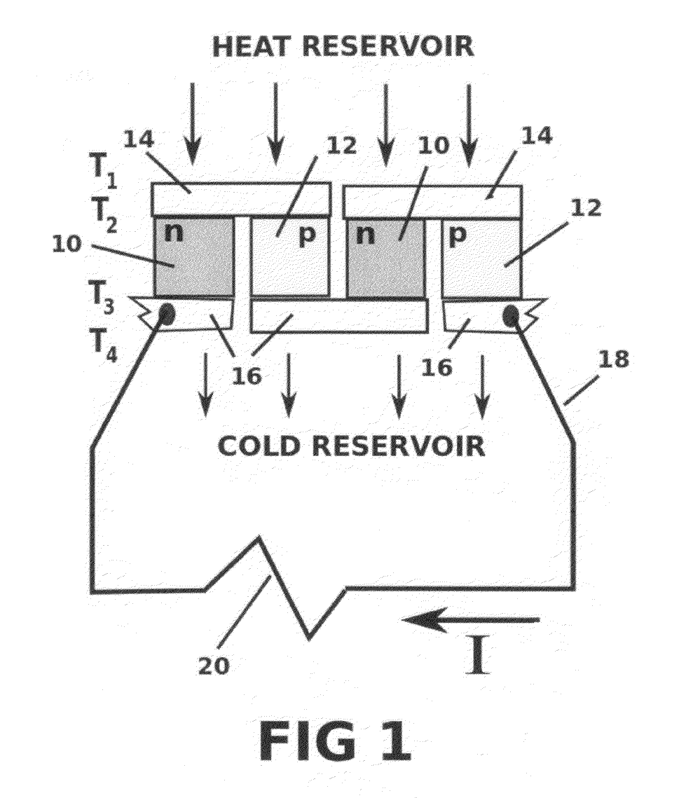

FIG. 1 depicts a four element thermoelectric device. N-type thermoelements 10 and p-type thermoelements 12 are connected in thermal parallel and electrical series through top electrical conductors 14 and bottom electrical conductors 16. In a thermoelectric generator, the heat flow is from hot to less hot, so in the FIG. 1 depiction, the heat reservoir is on the top and heat energy flows in a downward direction through the generator, with some of the heat energy being converted to electrical energy and the remainder flowing to the cold reservoir. The electrical conductors 14 and 16 are generally chosen to be a metallic conductor such as copper or nickel in order to have very low electrical resistance. Since good electrical conductors such as copper or nickel are also good thermal conductors, there is generally a minimal temperature drop across the top conductors 14, so that the temperature, T₁, at the top of top electrical conductor 14 is only slightly higher than the temperature T₂ at the bottom of top electrical conductor 14. Likewise, the temperature T₃ at the top of bottom electrical conductor 16 is only slightly higher than the temperature T₄ at the bottom of bottom electrical conductor 16. An electrical wire 18 is used to attach the thermoelectric generator to an electrical load 20. When heat flows in the direction indicated, it will cause an electrical current flow in electrical wire 18 through the electrical load 20 in the direction shown. If the electrical load 20 is assumed to have an infinite resistance, that represents an open circuit condition and allows the calculation of the open circuit voltage V_{OC}. In FIG. 1, a voltage is induced across each of the n-type thermoelements according to the equation

Vₙ=Sₙ×(T₃−T₂) (4)

where Sₙ is the thermopower (a material constant) that is characteristic of the n-type thermoelement 10, and T₂ and T₃ are the temperatures at the top and bottom of each of the n-type thermoelements 10. Likewise, a voltage is induced across each of the p-type thermoelements according to the equation

Vₚ=Sₚ×(T₃−T₂) (5)

where Sₚ is the thermopower of the p-type thermoelement 12 and T₂ and T₃ are the temperatures at the top and bottom of both of the p-type thermoelements 12. The thermopower for n-type materials is negative and for p-type materials is positive, so the total open circuit voltage for the four thermoelement generator in FIG. 1 is

$$\begin{matrix}{V}_{OC} = - {S}_{p} \times ( {T}_{3} - {T}_{2} ) + {S}_{n} \times ( {T}_{3} - {T}_{2} ) - {S}_{p} \times ( {T}_{3} - {T}_{2} ) + {S}_{n} \times ( {T}_{3} - {T}_{2} ) \\ = 2 ( {S}_{p} - {S}_{n} ) ( {T}_{2} - {T}_{3} ) .\end{matrix} \qquad ( 6 )$$

It should be noted that the thermopower is temperature dependent but an assumption of the thermopower values as evaluated at a temperature midway between the endpoint temperatures will generally yield valid results. The n-type and p-type thermoelectric material that is used in a generator will almost certainly differ from one another in the magnitude of their material constants S, σ and κ. But for convenience and without loss of generality, we will assume that the n-type thermoelectric material has the same thermal and electrical conductivity as the p-type material, and the same magnitude of thermopower. For the purposes of the following discussion, we assume that in building a thermoelectric device, the dimensions of the n-type and p-type elements will be identical. In reality, the preferred n-type and p-type thermoelectric materials for a given application may have different properties and it may be desirable to adjust the dimensions of the n-type thermoelements relative to the p-type thermoelements in order to optimize the design.

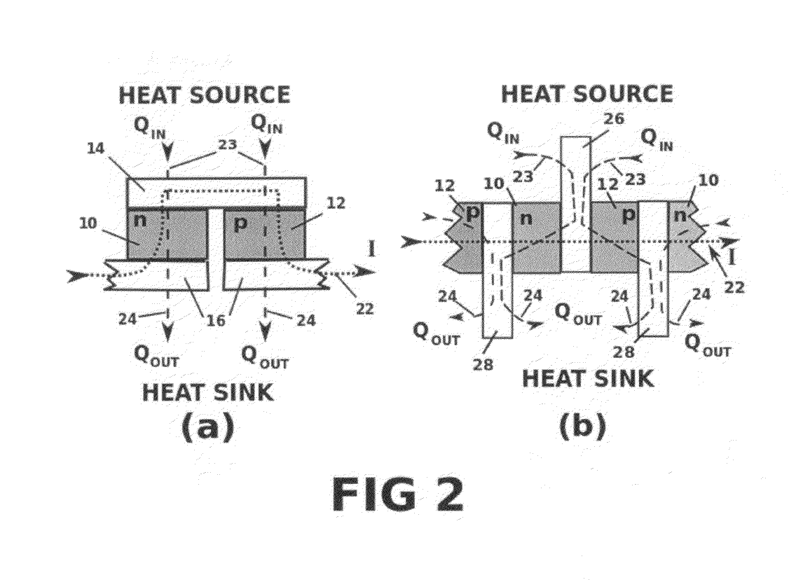

FIG. 2 depicts two generic topologies for thermoelectric devices. The most common is the so-called pi topology which has a side view depicted in FIG. 2(a). From the side view, it is easy to see that for a two thermoelement system, the side view looks similar to a Greek letter pi (π). This is the same topology depicted in the four element generator in FIG. 1, and it is probably the most common configuration used in status quo thermoelectric devices. In the pi topology in FIG. 2(a), heat energy flux, Q_{IN}, 23, flows from the heat source (equivalently, heat reservoir) into the top conductor 14 through the n-type thermoelement 10 and p-type thermoelement 12, through the bottom conductors 16 and into the heat sink. For the purposes of this discussion, we assume that the n-type thermoelements 10 and p-type thermoelements 12 have the same thermal conductivity, κ. Even though the heat energy flux 23 is depicted in FIG. 2(a) as two inputs from the heat source, the heat energy flux is actually distributed over the top electrical conductor so that the heat flux density per unit area is approximately constant across the top electrical conductor 14 and into the thermoelements 10 and 12. In the same way, the heat energy flux exiting the bottom electrical conductors 16, may be assumed to be uniformly distributed. The total heat energy flux that exits the bottom conductors 16 is somewhat less than the total heat energy flux that enters the top conductor 14, since some of the incoming heat energy flux is converted to electrical power which is then delivered to an external load via electrical current 22. That is the reason for distinguishing Q_{IN} from Q_{OUT}. It should be noted that in the pi topology, the directions of heat flow and electrical current flow within the thermoelements are approximately parallel, while the directions of heat flow and electrical current flow are approximately perpendicular in the electrical conductors 14, 16. One advantage to the pi topology is that there is relatively little thermal resistance introduced by the top and bottom conductors 14,16 since these are generally good thermal conductors, particularly if they are relatively thin in cross-section. As a result, there is relatively little temperature drop across these conductors 14,16. On the other hand, the path for electrical current 22 is perpendicular to the direction of heat flow and this can present significant electrical resistance within conductors 14,16, particularly if those electrical conductors 14,16 are thin. This highlights the trade-off in the choice of thickness for conductors 14,16.

FIG. 2(b) depicts a side view of a multielement generator that has a so-called Oersted topology. The heat source is on top and heat energy flux flows in a downward direction through the generator and into the heat sink. In this topology, n-type thermoelements 10 and p-type thermoelements 12 are sandwiched between hot paddles 26 and cold paddles 28. The hot paddle 26 and cold paddles 28 are chosen to be good electrical conductors and good thermal conductors. Some example materials that might be suitable are copper, aluminum or nickel. The hot paddle 26 serves as a conduit of heat energy flux Q_{IN} 23 into the generator where it then flows through the adjacent n-type and p-type thermoelements to the cold paddles 28, which serve as conduits for heat energy flux Q_{OUT} into the heat sink. Electrical current flow 22 occurs in a horizontal direction as shown. The paddles 26,28 used in the Oersted topology add relatively little electrical resistance to electrical current flow 22 since they have a broad area contact with the thermoelements. However, the paddles can introduce significant thermal resistance since the path for heat energy flux to flow into the generator enters through the cross-section of the paddles 26,28. So, in contrasting the topologies in FIG. 2(a) and FIG. 2(b), it is seen that as a general rule, the pi topology introduces fewer thermal parasitics while the Oersted topology introduces fewer electrical parasitics.

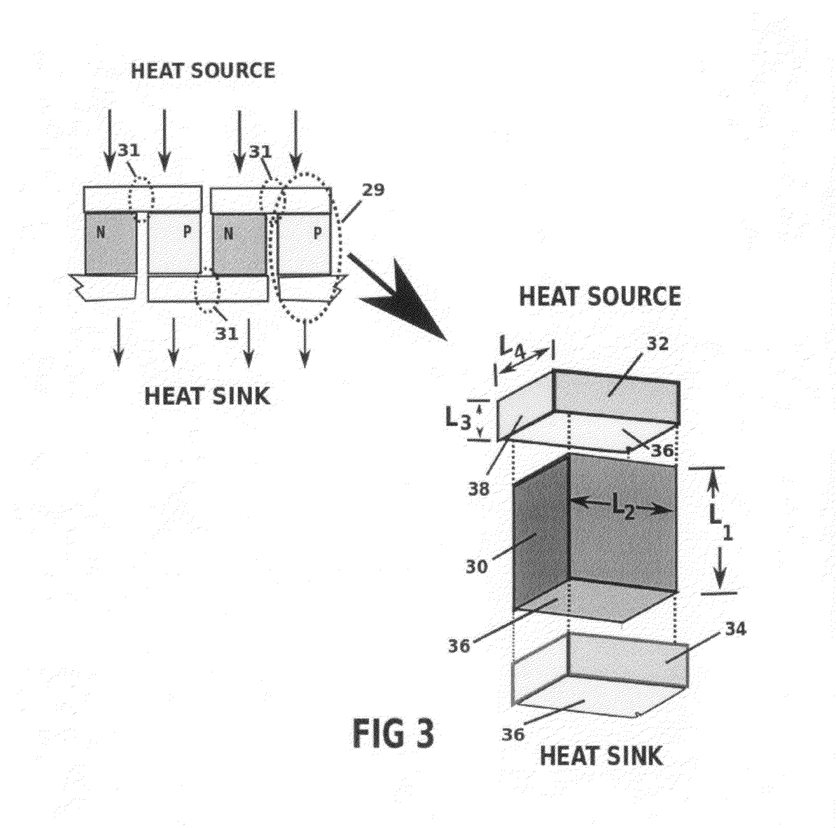

FIG. 3 depicts an exploded view of one leg 29 of a multielement pi topology generator. Thermoelectric leg 29 is expanded and skewed slightly to highlight the various dimensions and features of this individual leg. Thermoelectric pellet 30 is connected to a top conductor 32 and a bottom conductor 34. As shown in FIG. 3, the pellet 30 has a height (or thickness) of L₁, a depth of L₄ and a length of L₂. The top conductor 32 has a height (thickness) of L₃ and the same depth L₄ as the pellet 30. Although there is always a slight conductor “overhang” 31 between legs due to the need for adjacent thermoelements to be interconnected without shorting each other out, this overhang is ignored in our exploded pellet, so for the purposes of this discussion, we assume that the length of the top conductor 32 is the same as of the pellet 30, namely L₂. For the following discussion, we assume that the bottom conductor 34 has the same dimensions as the top conductor 32.

In FIG. 3, there are two cross-sections of particular significance. The cross-sectional area 36 of the thermoelectric pellet 30 as well as the cross-sectional area of the top and bottom conductors 32,34 is the area normal to the direction of heat energy flux passing from the heat source to the heat sink. The cross-sectional area 38 is the area normal to the electrical current flow coming out of/going into the leg 29. In analyzing thermoelectric system performance, particularly with an eye on parasitics, the relative L₁, L₂ and L₃ dimensions are important as are the material properties of the thermoelectric pellet 30 and conductors 32,34. However, power generation scales linearly to the depth L₄ of the leg 29. That is, when material constants and the dimensions L₁, L₂ and L₃ are held fixed, changing the size of L₄ by an arbitrary factor X causes an change in power production by that same factor X and does not impact the conversion efficiency. This is because the L₄ direction is perpendicular to both the direction of electrical current flow and the direction of heat energy flux and so parasitic drops in temperature, ΔT, across nonactive components are not affected by the L₄ parameter. Likewise, parasitic drops in voltage, ΔV, are not affected by the L₄ parameter.

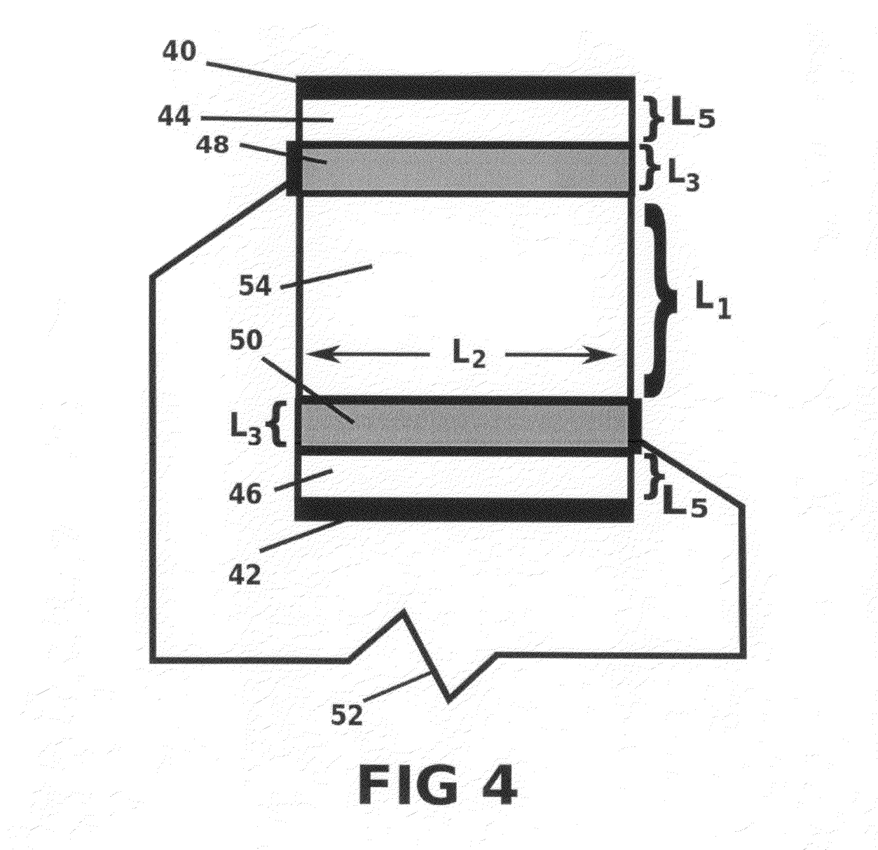

FIG. 4 depicts a side view of a model that is used to determine power generation from a single thermoelectric leg. The depth (dimension into the page and not shown) is arbitrary, since, as described earlier, the power that is produced is proportional to the depth, so optimization efforts can assume any arbitrary depth. The heat source is modeled as an infinite heat reservoir having a fixed temperature T_{H} along the line 40 that is in thermal series with a layer 44 that represents a thermal resistance. The term “infinite heat reservoir” is used to denote the ability to source as much heat energy flux as necessary to maintain a fixed temperature, in this case, T_{H}. The heat sink is modeled as an infinite cold reservoir having a fixed temperature T_{C} along the line 42 that is in thermal series with a layer 46 that represents a thermal resistance. Thermal resistances 44 and 46 are modeled as layers of thickness L₅ and constant thermal conductivity. The term “infinite cold reservoir” is used to denote the ability to absorb as much heat energy flux as is necessary to maintain a fixed temperature, T_{C}, along the line 42. The heat source temperature is greater than the heat sink temperature, so T_{H}>T_{c}. Thermal resistances 44,46 introduce parasitic temperature drops and they are included to reflect the reality that thermoelectric devices can never fully exploit the temperature differences between two reservoirs—there are always thermal resistances present that reduce the ΔT across the active thermoelements. For example, in a heat exchanger that is designed to transfer heat from one fluid to another, the heat energy flux that passes from one side to another is limited by the thermal resistance of the wall of the heat exchanger and is also limited by temperature drops across boundary layers close to the wall of the heat exchanger. Those temperature drops reflect thermal resistances. So, while the fluid temperatures far away from the wall may be modeled as belonging to infinite source and sink, the thermal resistances contributed by boundary layers limit the amount of heat that passes from one fluid to another. In FIG. 4, these thermal resistances are lumped into the layers 44 and 46.

The thermoelectric pellet 54 has a length of L₂ and a height denoted by L₁. The pellet 54 is sandwiched between electrical conductors 48 on the hot side and 50 on the cold side. These electrical conductors have a length denoted by L₂ and a height denoted by L₃. An electrical load 52 is attached between the top conductor 48 and the bottom conductor 50. on the, respectively, left top 48 and right bottom 50 conductors. Using a model based upon the setup in FIG. 4, a finite element based simulation can be undertaken to examine the relative importance of the L₁, L₂ and L₃ parameters for power generation in a single thermoelectric leg. Since a multielement, pi topology thermoelectric generator may be built from the connection of an arbitrary number of these legs in electrical series and thermal parallel, the optimization of the dimensions for a single leg gives guidance for the optimization for a multielement generator.

An overview of the source of various parasitics can be captured from an examination of FIG. 4. The total temperature difference between the line of constant hot temperature 40 and the line of constant cold (less hot) temperature 42 represents the most potential for generating power. Ideally, this is the temperature difference that can be placed across the active portion of the generating leg, namely, the thermoelectric pellet 54. In actuality, there will be undesirable temperature drops between the line of constant hot temperature 40 and the line of constant cold temperature 42 that detract from the desirable temperature drop that appears across thermoelectric pellet 54. These undesirable temperature drops reduce the power generating capability of the thermoelectric leg and are thus considered to be parasitic. There are parasitic temperature drops across the topside and bottomside thermal resistances 44,46. Even though conductors 48 and 50 are made of materials that have an inherently low thermal resistance (good electrical conductors will also be good thermal conductors due to electronic heat transport) there will still be some parasitic temperature drops, although these are generally negligible compared to the topside and bottomside thermal resistances 44,46.

Any electrical resistance in the series electrical circuit connecting to the load 52, including the top conductor 48, the thermoelectric pellet 54 and the bottom conductor 50, reduces the voltage across the load 52 and represents a power loss. These resistances represent electrical parasitics. It is not possible to isolate the portion of the electrical resistance due to the pellet 54, the portion due to the top conductor 48 and the portion due to the bottom conductor 50, or to calculate their value independently, since there is an interaction between these components. For this reason, it is necessary to consider a distributed parameter model of a single leg that can capture the relevant thermal and electrical dynamics.

Although the above discussion on the FIG. 4 model for a thermoelectric leg has centered around generation, a similar discussion could be made about heat pumping. If the electrical load 52 is replaced by a voltage source, it causes electrical current to flow through the series connection of bottom conductor 50, thermoelectric pellet 54 and top conductor 48. The amount of electrical current that flows is limited by the electrical resistance of the thermoelectric pellet 54 as well as by electrical resistances introduced by the top and bottom conductors 48,50. So it is desirable to minimize the contribution to electrical resistance of top and bottom conductors 48,50. When an electrical current flows through thermoelement 54, it causes a proportional heat energy flux to flow from top conductor 48 to bottom conductor 50. The amount by which that active heat flow impacts the temperatures on the top and bottom of the module are governed by the topside 44 and bottomside 46 thermal resistances. Large values of thermal resistance will reduce the effectiveness of the heat pump.

A case study based on the model in FIG. 4 allows the determination of some general construction guidelines for optimizing leg performance from a thermoelectric generation standpoint. A finite element simulation model is used. The thermal resistances 44,46 are assumed to have a height of L₅=1 mm and to have constant material parameters of

σ=0,S=0,κ=1.42 W/mK (7)

where again we note that σ is electrical conductivity, S is thermopower and κ is thermal conductivity. The top and bottom conductors 48,50 are copper, having a thickness (height) of L₃=0.1 mm and constant material parameters of.

σ=5.8e7Ω⁻¹ m⁻¹,S=1.84e-6 V/m,κ=401 W/mK. (8)

The thermoelectric pellet is p-type bismuth antimony telluride having temperature dependent material properties:

σ(T)=1.14×10⁵−596T+1.25T²Ω⁻¹ m⁻¹ (9)

S(T)=2e-4+6.29×10⁻⁷T−3.25×10⁻⁹T² V/K (10)

κ(T)=1.47−3.78×10⁻³T+2.76×10⁻⁵T² W/mK (11)

where T is the temperature in degrees Celsius. The temperature at the line of constant hot temperature 40 is 225 degrees Celsius and the temperature at the line of constant cold temperature 42 is 50 degrees Celsius. For the purposes of the simulation, the L₄ dimension of our pellet, which is the dimension in the direction that is perpendicular to both the heat flow and the electrical current flow, is taken to be 1 mm. We note that the combination of a bismuth telluride based thermoelectric material with a copper conductor is very common since bismuth telluride thermoelectrics have a high figure-of-merit, Z, and copper is an excellent electrical conductor. However, when copper is used in a direct connection to tellurium based alloys, thermal diffusion of copper into the thermoelectric can cause a reduction in performance. A common technique to avoid this is to use a very thin nickel plating between copper and thermoelement, preventing diffusion while retaining the attractive material properties of copper and bismuth telluride systems. For ease of simulation and without loss of generality, we ignore the plating requirement in calculating optimal design requirements.

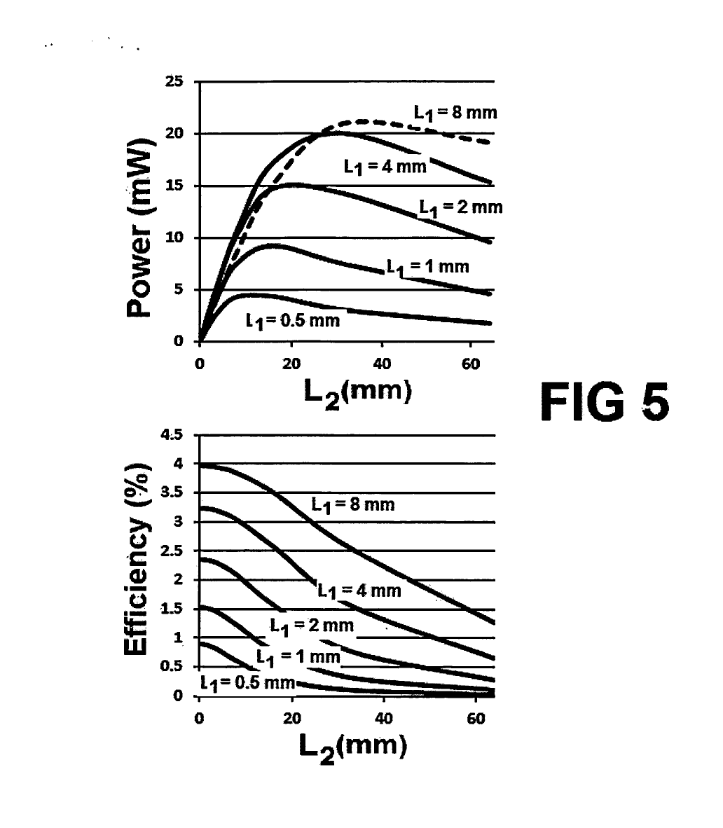

FIG. 5 depicts a plot showing the maximum power and corresponding efficiency that can be obtained from the one leg generator depicted in FIG. 4 with the parameters described above. Refering to FIG. 4, these plots are generated by using a finite element simulation for different thickness (height) L₁ and width L₂ of the thermoelectric pellet 54 and then calculating the power delivered to the load 52. For each (L₁,L₂) set, the load is first adjusted to ensure maximum power delivery. This is calculated as

$${R}_{max} = \frac{{V}_{OC}}{{I}_{SC}} \qquad ( 12 )$$

where V_{OC} is the open circuit voltage and is calculated by determining the voltage across the load 52 when the load 52 has a very high resistance (eg: 10⁶Ω) and where I_{SC} is the short circuit current and is calculated as the current through the load 52 when the load 52 has a very low resistance (eg: 10⁻⁸Ω). So by attaching a load calculated from equation (12) under a variety of (L₁,L₂) conditions, the plots corresponding to power generation and the corresponding efficiency are determined and portrayed in FIG. 5. In the lower plot, the corresponding efficiency is determined as the ratio of generated power to total heat energy flux passing through the leg. From the lower plot, it is seen that efficiency increases with increasing thicknesses L₁, but as the upper plot reveals, increasing L₁ does not translate to improvements (increases) in maximum power generation. It is also interesting to note that there is a reduction in efficiency with increasing L₂. This is due to increasing electrical parasitics that accompany an increase in pellet and conductor length.

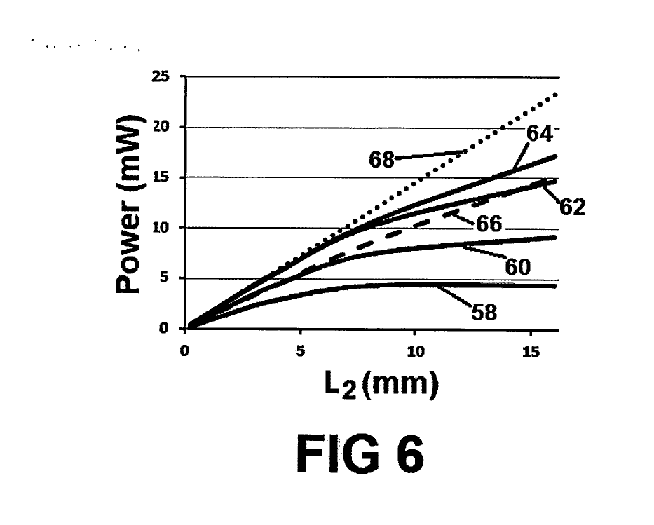

FIG. 6 depicts a detail of the maximum power generation for different cases of thermoelectric element thickness, L₁, as the length L₂ of the leg is varied from 0 millimeters to 16 millimeters. From FIG. 6, it is evident that by increasing the thermoelectric thickness, it is possible to increase the maximum generated power as seen in curves 58, 60, 62 and 64 (corresponding respectively to L₁=0.5, 1, 2 and 4 millimeter), but there is a diminishing return and there is a reduced generated power for curve 66, corresponding to L₁=8 mm. The improvement for the L₁=0.5, 1, 2 and 4 millimeters trend can be explained by the reduced influence of thermal parasitics, since as the thermoelectric thickness is increased, more of the temperature difference between the heat source and the heat sink appears across the thermoelectric pellet. Offsetting this trend is the increasing electrical resistance which accompanies increasing thermoelectric thickness. So, as an example, for a thermoelectric length of L₂=10 mm, each doubling of the thermoelectric thickness L₁ from L₁=0.5 mm to 1 mm to 2 mm to 4 mm (curves 58-64) causes an increase in power, but there is a diminishing return with increasing thickness. When the thickness is increased to L₁=8 mm (curve 66), the generated power is actually less than that produced for the cases of L₁=2 mm and L₁=4 mm (curves 62 and 64). Another observation from FIG. 6 is that for all of the curves of constant L₁, 58-66, the total generated power increases as the length L₂ of the thermoelectric pellet increases, although the rate of power increase is not linear and rolls off with increasing L₂. This roll-off is due to the increasing electrical resistance which reduces the power that can be delivered to the load.

If the initial slope for curve 64 is extrapolated, it yields a line 68. This corresponds to the partial derivative of maximum generated power with respect to thermoelectric length, L₂, with other variables held constant. This line expresses a boundary for improvements in maximum power generation with increasing L₂ and is an important component for determining optimal dimensions for the legs in a pi configured thermoelectric generator. In FIG. 6, for curves 62 and 64, when the length L₂ exceeds 7 millimeters, then there is a diminishing incremental maximum generated power that is obtained with further increases in length L₂, and this is one of the considerations in the design of a generator. From a systems standpoint, there are competing requirements for the design of a thermoelectric generator. The curves in FIG. 6 yield useful design guidance.

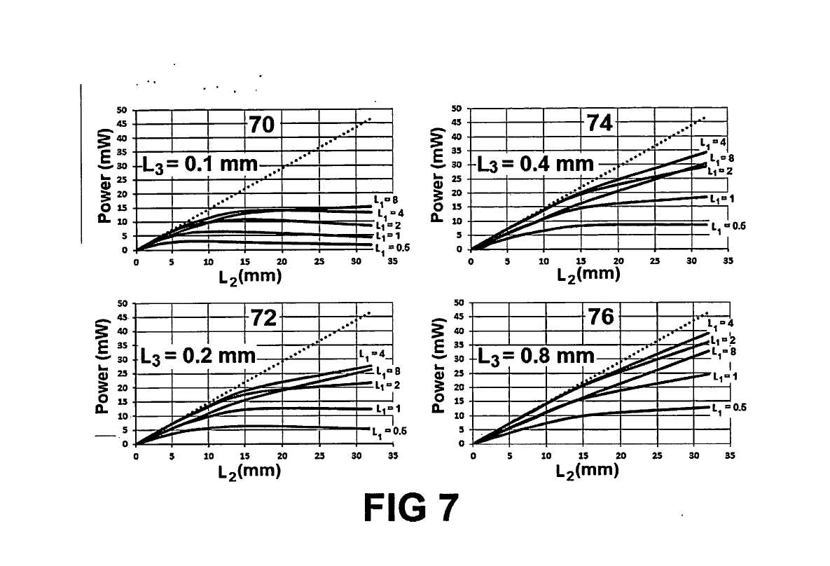

FIG. 7 depicts plots illustrating the influence of different conductor thicknesses L₃ in determining the maximum power generation capability for a thermoelectric leg. This plot was generated using finite element simulations based on the model in FIG. 4 and using the parameters in equations (7-11). Plot 70 corresponds to the case of L₃=0.1 mm and gives the same curves as the curve for maximum power in FIG. 6, for the range of 0<L₂<32 mm. Plots 72, 74 and 76 show generated power for, respectively, conductor thicknesses of L₃=0.2 mm, L₃=0.4 mm and L₃=0.8 mm. From these plots it can be seen that as conductor thickness increases, the maximum powers for any given combination of L₁ and L₂ increase. This is due the fact that thicker conductors generally yield reduced parasitic electrical resistance. However, thicker conductors introduce parasitic thermal resistances, so, beyond a certain value of L₃, the reduction in generated power due to temperature drops across the conductors will overshadow any benefit from reduced electrical resistance.

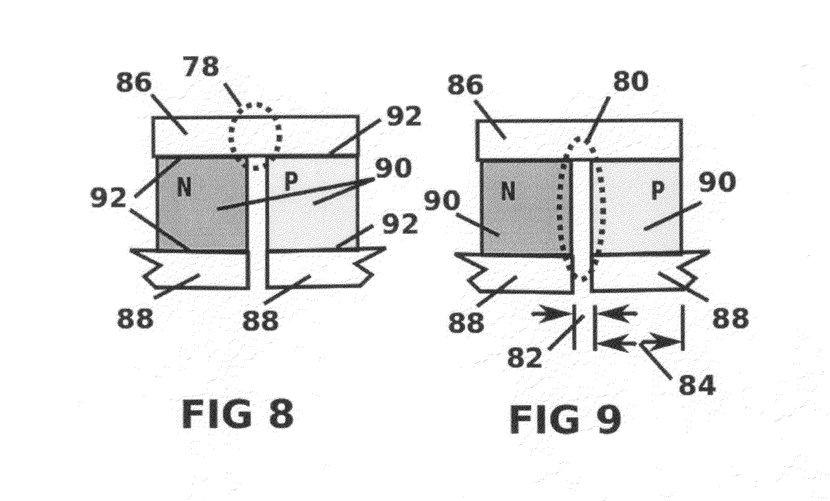

FIG. 8 and FIG. 9 highlight two regions in a pi connected thermoelectric generator that can detract from generation performance. In FIG. 8, the electrical attachment 78 that connects adjacent thermoelectric elements is a necessary conduit for electrical current flow, but is also a contributor of electrical resistance that reduces generator performance.

In FIG. 9, the region 80 between adjacent thermoelectric elements is an electrical insulator and could be vacuum, air, foam or another material. This region 80 does not contribute to electrical generation. Furthermore, any heat flow out of conductor 86 that passes through region 80 represents a “thermal leak”, that is, heat energy flux that bypasses the active thermoelectric elements 90 without producing electrical power and thereby reduces the heat to electricity conversion efficiency. There will always be a dielectric filled gap 82 between adjacent thermoelements in order to provide electrical insulation. That dielectric can be vacuum, air, foam, aerogel or another largely electrically nonconductive material.

From the triple standpoint of minimizing nonproductive area, limiting parasitic electrical resistance due to the FIG. 8 electrical attachment 78 between legs, and limiting parasitic thermal resistance due to the FIG. 9 gaps 82 between adjacent thermoelements, it is desirable to have a length 84 for the thermoelements 90 that is relatively large with respect to the gap 82. There is one other performance impacting factor that bears mention and this relates to the interface 92 between the conductors 86,88 and the thermoelements 90. The interface 92 can introduce electrical contact resistance due to a poor connection between thermoelement 90 and conductor 86 or 88. As for any electrical parasitic, voltage drops across contact resistances serve to reduce the voltage available to an electrical load. The interface 92 can also introduce thermal contact resistance which can result in a parasitic temperature drop that detracts from the temperature difference that can be developed across the thermoelement 90.

A key requirement for a thermoelectric generator is to have a heat energy flux passing through thermoelectric elements in order to produce electricity. Heat transfer is a very common requirement for applications ranging for petroleum refining to cooking, so a perfect home for a thermoelectric generator is deployment as, or as part of, a surface separating hot and cold in a device designed for heat exchange, a so-called heat exchanger.

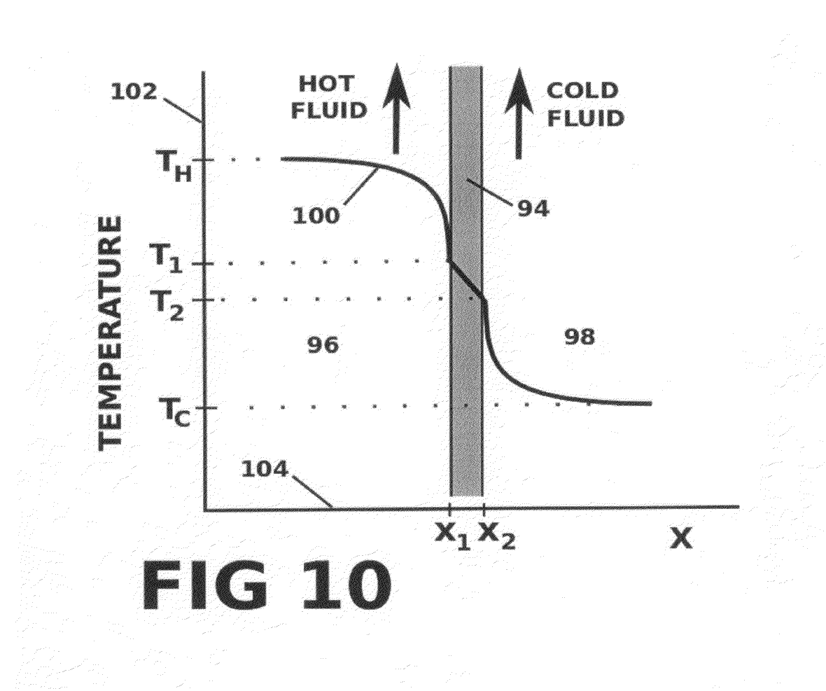

FIG. 10 depicts temperature as a function of position in the vicinity of a heat exchanger wall. Heat exchangers are designed to transfer heat energy from a higher temperature fluid to a lower temperature fluid. For some applications, radiation or conduction may be the mechanism for heat transfer away from one side of the heat exchanger wall, in which case, there is no fluid involved, but without loss of generality the following discussion will be confined to fluid systems. Heat exchangers can go by many names including boilers, recuperators, condensers and radiators. In FIG. 10, a heat exchanger wall 94 separates a hot fluid 96 and a cold fluid 98, both flowing “into the page”, where hot and cold are relative terms that simply indicate the temperatures of two fluids relative to each other. In FIG. 10, the hot fluid 96 and cold fluid 98 are arbitrarily defined as flowing in the same direction (“into the page”) on either side of the wall 94, although in some embodiments one fluid could flow in an opposite direction to the other fluid. The following discussion is valid for either configuration. The temperature of the hot fluid 96 is assumed to have a temperature T_{H} at some distance sufficiently far from the wall 94 that the fluid is relatively unaffected by the temperature of the wall 94. Likewise, the temperature of the cold fluid 98 is T_{C} at some distance sufficiently far from the wall 94 that the fluid is unaffected by the temperature of the wall 94. A curve 100 of temperature as a function of vicinity to the heat exchanger wall 94 illustrates the way in which temperature changes in the fluid. In curve 100, temperature is indicated on the vertical axis 102 and displacement, X, is indicated on the horizontal axis 104. The heat exchanger wall has a thickness of x₂−x₁. In a heat exchanger, on the hot side 96, much of the temperature reduction in the fluid appears in the fluid boundary layers close to the heat exchanger wall 94. The actual amount and nature of the temperature drop depends on many factors including the heat capacity and viscosity of the hot side fluid 96, the velocity of the hot side fluid 96 and the surface roughness of the heat exchanger wall 94. Likewise, much of the temperature drop on the cold side of the heat exchanger wall 94 occurs at the boundary layers of cold fluid 98 that are next to the heat exchanger wall 94. The result is that the wall 94 itself may have a relatively low temperature drop T₁−T₂. The amount of heat energy flux that is transported through a unit area of the heat exchange wall can be calculated by Fourier's equation:

$$Q = {κ}_{wall} \frac{d T}{d x} \qquad ( 13 )$$

where Q is heat energy flux in W/m², K_{wall} is thermal conductivity of the wall 94 in the units W/mK and is a material constant corresponding to the wall material, T is the temperature in Kelvin and x is the direction normal to the heat exchanger wall 94. For relatively small changes in temperature, the thermal conductivity can be assumed to be constant, and the derivative, dT/dx, is a constant and corresponds to the slope of the curve 100 between a temperature of T₁ on the hot side of the wall 94 and the temperature of T₂ on the cold side of the wall 94. Accordingly, equation (13) becomes:

$$Q = {κ}_{wall} \frac{( {T}_{1} - {T}_{2} )}{( {x}_{1} - {x}_{2} )} . \qquad ( 14 )$$

An important requirement for heat exchanger design is to expedite the transfer of thermal energy from one side of the exchanger to the other side. Heat energy flux that is transferred from one side of the wall 94 to the other is governed by equation (14). An inspection of equation (14) suggests general ways to increase the heat transfer through the wall 94. First, the material that makes up the wall 94 can be chosen to have a high thermal conductivity (that is, increase K_{wall}). Second, the thickness of the wall 94 can be reduced, that is, decrease the difference x1−x2. While both of these first two approaches will result in increases in heat transfer, they also cause a reduction in the temperature drop, T₁−T₂, across the wall, which offsets some of the gains in heat transfer. A more significant approach is to reduce the temperature drops at the boundary layers, thereby causing more of the temperature drop between the hot fluid 96 and the cold fluid 98 to appear across the wall 94 (that is, increase the difference T₁−T₂). This third approach can be done by increasing fluid velocity, by introducing turbulence in the hot fluid flow 96 and cold fluid flow 98, and by increasing the effective surface area of the wall 94. As will be seen, the present invention leads to a design that both increases turbulence and surface area as a byproduct of adding thermoelectric generation to a heat exchanger wall.

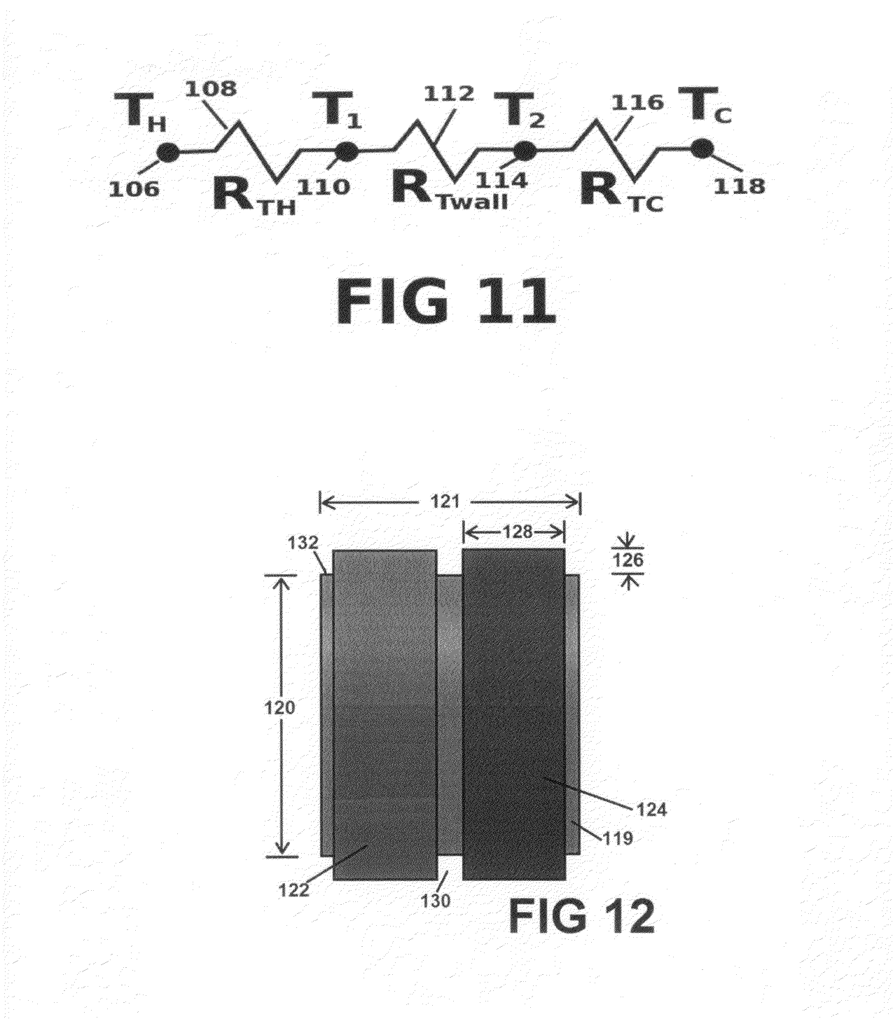

FIG. 11 depicts a lumped thermal model for a heat exchanger wall, denoting various temperatures and thermal resistances. Node 106 is a point of constant temperature T_{H}. This is the temperature of the hot fluid at a sufficient distance from the heat exchanger wall that it's temperature is relatively unaffected by the wall temperature. Hotside thermal resistance R_{TH} 108 is the thermal resistance between node 106 and the hotside wall 110 of the heat exchanger. R_{TH} 108 reflects the thermal resistance in the fluid boundary layers next to the hotside wall of the heat exchanger. The hotside wall of the heat exchanger 110 has temperature T₁ and the coldside wall of the heat exchanger 114 has temperature T₂. The thermal resistance of the wall of the heat exchanger is R_{Twall} 112. Coldside thermal resistance R_{TC} 116 is the thermal resistance between nodes 114 and 118. R_{TC} 116 reflects the thermal resistance in the fluid boundary layers next to the hotside wall of the heat exchanger. Node 118 is a point of constant “cold” temperature T_{C}, where T_{C}<T_{H}. A constant heat energy flux, Q, flows from T_{H} to T_{C} through the thermal resistances 108, 112 and 116. Using this model, an expression for the temperature drop across the wall of the heat exchanger can be expressed as:

$${T}_{1} - {T}_{2} = ( {T}_{H} - {T}_{C} ) ( \frac{{R}_{Twall}}{{R}_{Twall} + {R}_{TH} + {R}_{TC}} ) . \qquad ( 15 )$$

From equation (15), it may be seen that the hotside and coldside thermal resistances, R_{TH} and R_{TC}, act as parasitic thermal resistances. Any reduction of these parasitic resistances will serve to increase the temperature difference, T₁−T₂, across the heat exchanger wall, and by equation (14), will result in increased heat energy flux, Q, passing through the heat exchanger wall and from the hot fluid to the cold fluid.

FIG. 12 depicts a side view of a thermoelectric tublet which is one way to implement a single thermoelectric couple. This device represents the base element about which multi-couple tubular thermoelectric devices can be built. The starting point is short tube 119 which serves as a substrate and has a length 121 and an outer diameter 120 and is constructed from a material that is both a good thermal conductor and a good electrical conductor. Candidate materials for short tube 119 might be copper, which is an excellent thermal and electrical conductor, or stainless steel, which has good thermal and electrical conductivity and has the added benefit of being resistant to corrosion. The material of the short tube 119 might also be selected from a host of other, generally metallic materials that can be extruded, cast or fabricated to form a tube. The reason that short tube 119 needs to be both an electrical conductor and a thermal conductor is that it will serve a multiple role of supporting the thermoelements mechanically, connecting them together electrically, and providing a low thermal resistance (equivalently high thermal conductivity) between the thermoelements 122 and 124 and fluids that will be flowing inside the short tube 119. Two rings of thermoelectric material are applied to the short tube 119 as a coating, separated by a gap 130. A ring of n-type thermoelectric coating 122 is applied to the outside of tube 119 with a uniform thickness 126. A ring of p-type thermoelectric coating 124 is applied to the outside of tube 119 with that same uniform thickness 126. The thickness 126 corresponds to the L₁ dimension of a thermoelectric pellet as depicted in FIG. 3.

The application of the n-type and p-type thermoelectric material onto the tube is preferably done using a spray coating technique which allows good electrical and mechanical bonding between the thermoelectric coatings 122, 124 and the tube 119 without the need for solder or another intermediate electrical bonding material. Spray coating is a generic term for manufacturing techniques that use a high velocity deposition of particles onto a substrate, sometimes accompanied by heat. One common spray coating technique is called plasma spray, where powder particles are heated to a molten condition before impacting the target. A second spray coating technique is called cold spray where powder particles may or may not be preheated but in solid state when they impact the substrate, where they subsequently deform and bond to the substrate and/or adjacent particles. Unlike vacuum deposition or other thin film approaches, spray coating techniques represent a practical approach for the volume application of thick coatings to a possibly irregularly shaped surface. With the right choice of technique and material set, an excellent thermal and electrical interface can be accomplished between coating and substrate. Although spray coating is the preferred application technique, the thermoelectric rings 122 and 124 could also be applied to the tube 119 using other techniques as a good thermal and electrical connection is achieved. These alternative techniques including thin film deposition, melting or the use of a solvent carrier.

The length 128 of thermoelectric coating 124 corresponds to the L₂ dimension of a thermoelectric pellet as depicted in FIG. 3. The rings of n-type and p-type thermoelectric material 122, 124 have an annular length that is approximately equal to πD, where D is the tube outer diameter 120. This length, πD, corresponds to the L₄ dimension as depicted in FIG. 3. When used as a thermoelectric generator, the nominal heat flow is from the interior of tube 119 to the outside, through the thermoelectric coatings, 122,124, or from the outside through the thermoelectric coatings 122,124 into the interior of the tube 119.

A reasonable design choice for the parameters for the thermoelectric tublet in FIG. 12 can be determined by an optimization study similar to that described in conjunction with FIGS. 4-7. Such a study depends upon the choice of thermoelectric material and the choice of the conductor type. For example, assume that the tube 119 in FIG. 12 is copper with a thickness of L₃=0.8 mm. Further assume that the p-type thermoelectric material 124 has the properties given in equations (9-11) and the n-type thermoelectric material 122 has the same properties except for a reversal in sign on thermopower. Then by reference to plot 76 in FIG. 7, we see that a reasonable choice of thickness and length is L₁=2 mm and L₂=25 mm. This is a compromise between a number of factors. Even though a thicker thermoelectric coating of L₁=4 mm yields slightly improved performance in terms of power production, this results in double the amount of required thermoelectric material and represents additional thermal resistance which may be objectionable in a heat exchanger. On the other hand, as guided by the efficiency curve in FIG. 5, thicker L₁ values allow higher conversion efficiencies, and this may dictate thicker thermoelectric coatings if efficiency is the guiding metric or if the thermal source has limited capacity. Choosing shorter element lengths, for example, L₂=15 mm would produce slightly more power per unit length, but would require more elements for a given total length resulting in more overhang waste (78 in FIGS. 8 and 80 in FIG. 9) for a multiple tublet tube. So, in FIG. 12, with a L₂ dimension 128 of 25 mm, a gap 130 between thermoelectric layers of 1 mm and a gap 132 between thermoelectric layers and the edge of the tube 119 of 1 mm, then a total tublet length 121 would be on the order of 53 mm. Since the changes in the diameter of the tube 119 only impact the L₄ dimension, the tube diameter need not be considered in determinations of the preferred tublet length 121 from a thermoelectric generation standpoint. We particularly note that from the standpoints of both power generation and thermoelectric efficiency as illustrated in FIG. 5, beyond a certain thermoelectric length, L₂, there are diminishing returns with increasing length. For this reason, tublet length must be chosen with care. Too long and it leads to an inefficient design where electrical parasitics predominate. However, if a thermoelectric generator is built from the connection of many very short tublets, the undesirable interconnection spaces (see FIG. 8 and FIG. 9) will detract from the overall system efficiency.

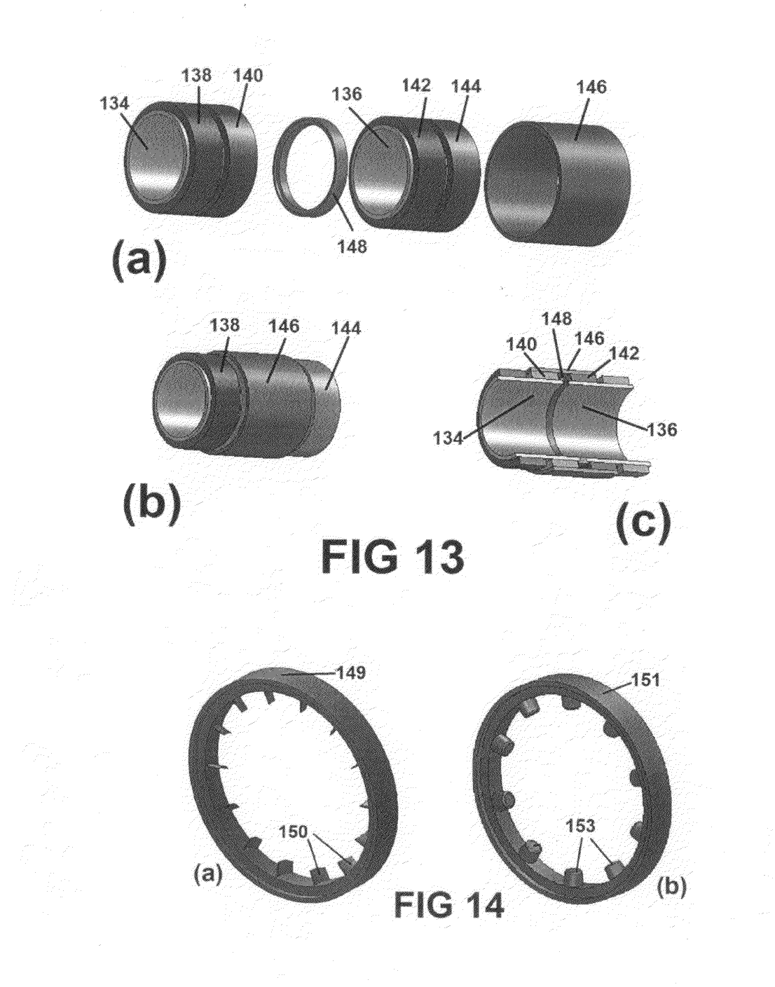

FIG. 13 depicts the way in which thermoelectric tublets like that in FIG. 12, each of which representing a thermoelectric couple, can be combined to form complete tubular thermoelectric generators which can, in turn, serve as the building blocks for a heat exchanger that produces electricity as a byproduct of the heat exchange. In the exploded view in FIG. 13 (a), a coating of n-type thermoelectric material 138 and a coating of p-type thermoelectric material 140 has been deposited onto a tube 134 to make one thermoelectric tublet. In a similar way, a coating of n-type thermoelectric material 142 and a coating of p-type thermoelectric material 144 has been applied to a tube 136 to form a second thermoelectric tublet. These two tublets are separated by an insulator 148. The main function of insulator 148 is to electrically separate tubes 134 and 136 so insulator 148 should have a relatively high dielectric constant. The insulator 148 may also serve as an alignment aide to maintain the tubes in a straight line during joining. The insulator 148 may also serve to seal the adjoining tubes 134 and 136 to retard fluid seepage from inside the joined tubes to the outside of the tubes. The insulator may also serve to incorporate fins or diverters that break up the fluid flow inside the composite (multiple tublet) tube. The insulator 148 may be made from a ceramic, fiber or organic material. Sleeve 146 is an electrically conductive tube that has a nominal length that is approximately the same as tubes 134 and 136 and that is used to mechanically join tubes 134 and 136. Sleeve 146 serves as a completion device that provides an electrical path to complete a series electrical connection between adjoining p-type and n-type thermoelements.

By combining the exploded elements from FIG. 13(a), two tublets may be combined into a single two-tublet thermoelectric generator as depicted in FIG. 13(b) wherein sleeve 146 has been attached over the coating of p-type thermoelectric 140, the insulator, 148, and the coating of n-type thermoelectric 142. The sleeve is a good electrical conductor and thermal conductor and serves to complete the two thermoelement generator built from thermoelectric rings 140 and 142. The sleeve must be electrically attached to thermoelectric rings 140 and 142 and this attachment may be made through any of a number of mechanisms. First, the sleeve can be expanded through heating and then slipped into place, where it then cools to form a press fit. Second, the sleeve can be designed to be slightly oversized and can then be fitted over a solder paste which is then melted to complete the electrical connection and to create a good electrical and mechanical bond. Finally, rather than have a prefabricated sleeve 146, the equivalent electrical connection may be made by spray coating a layer of conductor on top of thermoelectric rings 140 and 142 and insulator 148.

FIG. 13(c) shows a cutaway of the two tublet design and highlights the fact that even with a tubular design we have a pi topology thermoelectric generator, with the pi consisting of an inner tube 134 which serves as an electrical conductor, attached to a p-type thermoelement 140, attached to a top conductor (the sleeve) 146, then to the n-type thermoelement 142, and finally to the inner tube 136, which serves as the electrical conductor that completes the circuit. Spacer 148 fills the gap between n-type thermoelectric element and p-type thermoelectric element.

FIG. 14(a) depicts an embodiment of the insulator that is used between thermoelectric tublets. A bladed insulator 149 has internal blades 150 that serve to agitate the internal fluid flow as it flows past insulator 149. By the use of skewed blades 150, the internal fluid is directed internally in a swirling flow, causing fluid to traverse more surface area than it would in the absence of blades, 150, breaking up boundary layers and promoting heat transfer from the fluid to the tublet wall. FIG. 14(b) depicts another embodiment of the insulator that could be used between thermoelectric tublets. When fluid is forced past internal pegs 153 on the insulator 151, it creates a turbulence that serves to break up the boundary layers against the tube walls, thereby decreasing thermal resistance and increasing heat energy flux through the tube wall.

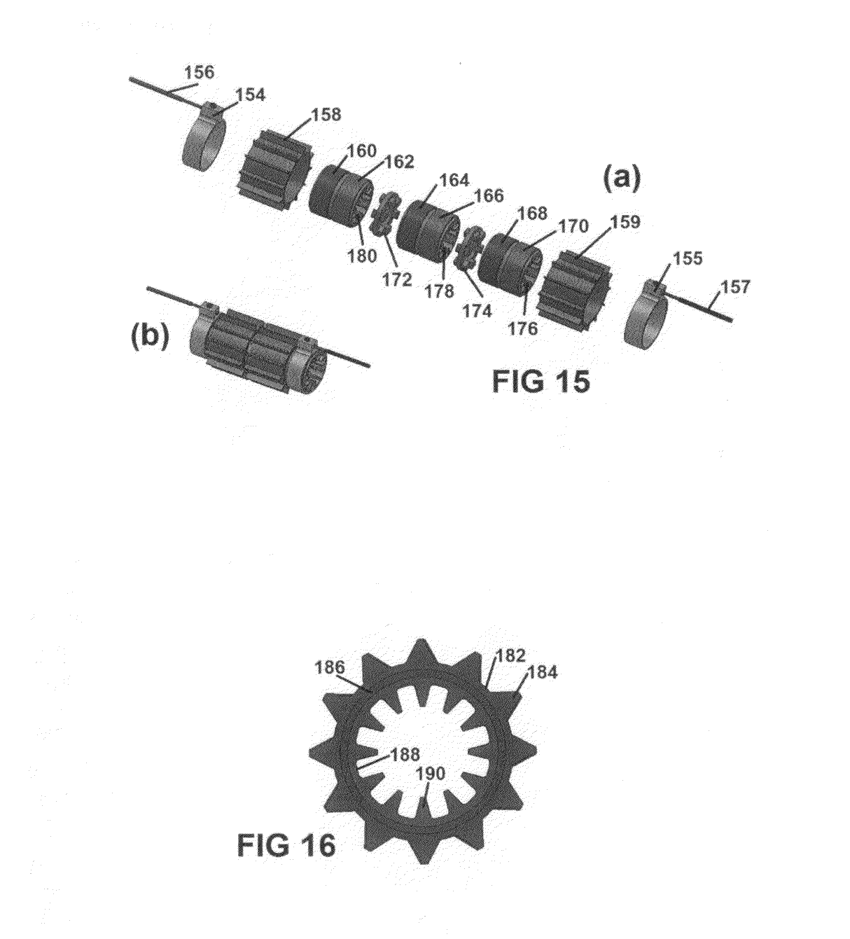

FIG. 15(a) depicts an exploded view of the components needed to build a six thermoelement tubular generator. There are three interior tubes 176, 178 and 180, each of which is shown having internal fins. The fins are optional and serve to provide a greater area for heat transfer when a fluid passes through the interior. Tube 180 has an applied ring of n-type thermoelectric material 160 and a ring of p-type thermoelectric material 162 to make a thermoelectric tublet. Similiarly, tube 178 has n-type and p-type rings 164 and 166 to make a second thermoelectric tublet and tube 176 has n-type and p-type rings 168 and 170 to make a third thermoelectric tublet. Insulators 172 and 174 serve to electrically isolate the tubes 176, 178 and 180. In the FIG. 15(a) embodiment, insulators 172 and 174 have raised areas that serve to align the internal fins of adjacent tubes. Conductive sleeve 158 serves to complete an electrical circuit between thermoelements 162 and 164. Likewise, conductive sleeve 159 serves to complete an electrical circuit between thermoelements 166 and 168. The conductive sleeves 158 and 159 are depicted with optional fins that increase the surface area to the outside fluid stream and thereby enhance thermal transport. End attachment collar 154 goes on top of, and is electrically and thermally bonded to n-type thermoelement 160. Likewise, end attachment collar 155 goes on top of, and is electrically and thermally bonded to p-type thermoelement 170. Electrical wires 156 and 157 are the means by which electrical power is extracted from the thermoelectric generator when there is a temperature difference between the inside and the outside of the complete tube assembly. FIG. 15(b) depicts the complete six thermoelement tubular thermoelectric generator. It may be desirable to apply dielectric coatings to all or selected portions of the tubular thermoelectric generator in order to protect it against contaminants or electrical leakages between elements. These coatings could be applied internal to the tube and/or externally. Such coatings are not depicted in FIG. 15(b) and will be optional, depending upon the specific application.

FIG. 15 highlights the way in which a complicated, multi-element, tubular thermoelectric generator can be built with just a few basic building blocks. The conductive inner tubes 176, 178, 180 can be extrusions, castings or can be cut from a longer extruded or fabricated tube. Likewise, the conductive sleeves 158,159 can be extrusions, castings or can be cut from a longer tube. Likewise, the conductive end collars 154, 155 can be extrusions, castings or cut from longer tubes. The inner tubes 176, 178, 180 require annular thermoelectric coatings (160, 162, 164, 166, 168, 170) of predetermined thickness and length. This process is easily automated for the mass production of thermoelectric tublets. Thermoelectric coatings can be added to the inner tubes with two coatings per inner tube. Alternatively, a single long tube can be prepared with 2*N alternating rings of n-type and p-type thermoelectric and can then be cut into N short tublets each representing a thermoelectric couple. The insulators 172, 174 can be stamped, cast, molded or otherwise fabricated. A number of tublets, insulators and sleeves can be connected to form thermoelectric generation tubes of many different lengths, which are then completed by adding a collar at each end. Then, a number of thermoelectric generation tubes can be combined in fluid parallel to make shell and tube heat exchangers/generators of a wide variety of geometries and dimensions. The advantage to the proposed design is that from a manufacturing standpoint, there are only four basic building blocks to be produced in high volume, namely, sleeves, insulators, collars and thermoelectric tublets (couples). Each of these four basic building blocks could be of fixed dimension. The flexibility of design results from the fact that these basic building blocks are of fixed dimension, they can be connected to make generation tubes of many different lengths. The thermoelectric tublets act as the base elements. The sleeves and collars act as completion elements and function to connect and complete the series electrical circuit. To build an N-couple generator requires N tublets and N+1 completion elements, namely N−1 sleeves plus two collars. For a given temperature gradient between inside and outside of a single tublet there will be a generated current I_{tublet} and a generated voltage V_{tublet}. When an arbitrary number, N, tublets are connected in series to form a tubular thermoelectric generator, that generator will produce the same generated current as each component tublet but with a voltage that is N times as great as that generated by a single tublet.

FIG. 16 shows a cross-section of the FIG. 15 tubular thermoelectric generator where the inner tube 188 and the outer sleeve 182 both have fins. Fins are optional and may be present only on the interior, only on the exterior, in both places as in FIG. 16, or they may be absent. These fins play a dual role in reducing thermal parasitics and reducing electrical parasitics. The optimal fin design for the outside fin 184 and inside fin 190 will depend upon a number of end-use system variables including the anticipated fluid velocity and fluid characteristics such as viscosity and heat capacity. Thermally, the fins reduce thermal resistance to the heat energy flux reaching (or leaving) the thermoelectric layer 186. First, they increase the surface area presented to the fluid. This has the effect of reducing the net thermal resistance from the fluid inside the inner tube 188 and the fluid outside the outer tube 182. Second, they serve to add impedance to the fluid flow, causing turbulence in the fluid at the boundary layers directly adjacent to the respective walls of the inner tube 188 or outside sleeve 182. This has the effect of breaking up the fluid boundary layer, thereby enhancing heat transfer. Thermally, the effect of the fins is equivalent to decreasing the L₅ thermal resistance thickness described in conjunction with FIG. 4.

The addition of fins to the inside tube and outside sleeve will result in reduced electrical parasitics. The reason for this is that the inside tube 188 and outside sleeve 182 serve as the electrical conductors that connect adjacent n-type and p-type thermoelements and complete the thermoelectric circuit. Electrical current flow through these electrical conductors is along the same axis as the internal fluid flow. The addition of fins serves to increase the cross-sectional area of the electrical conductors, resulting in reduced electrical resistance. Electrically, this is equivalent to increasing the L₃ conductor thickness described in conjunction with FIG. 4. So, with the proposed design, fins allow a combination of the best features of the pi and Oersted topologies while avoiding their weaknesses. In a conventional pi topology, when the electrical conductor is thickened, benefits from higher electrical conductance are offset by increases in thermal conductance. In an Oersted topology, when the thermal conductors (paddles) are thickened, benefits from lower thermal conductance are offset by decreases in electrical conductance. But in the present topology, adding fins serves to simultaneously increase both the electrical conductivity and the thermal conductivity.

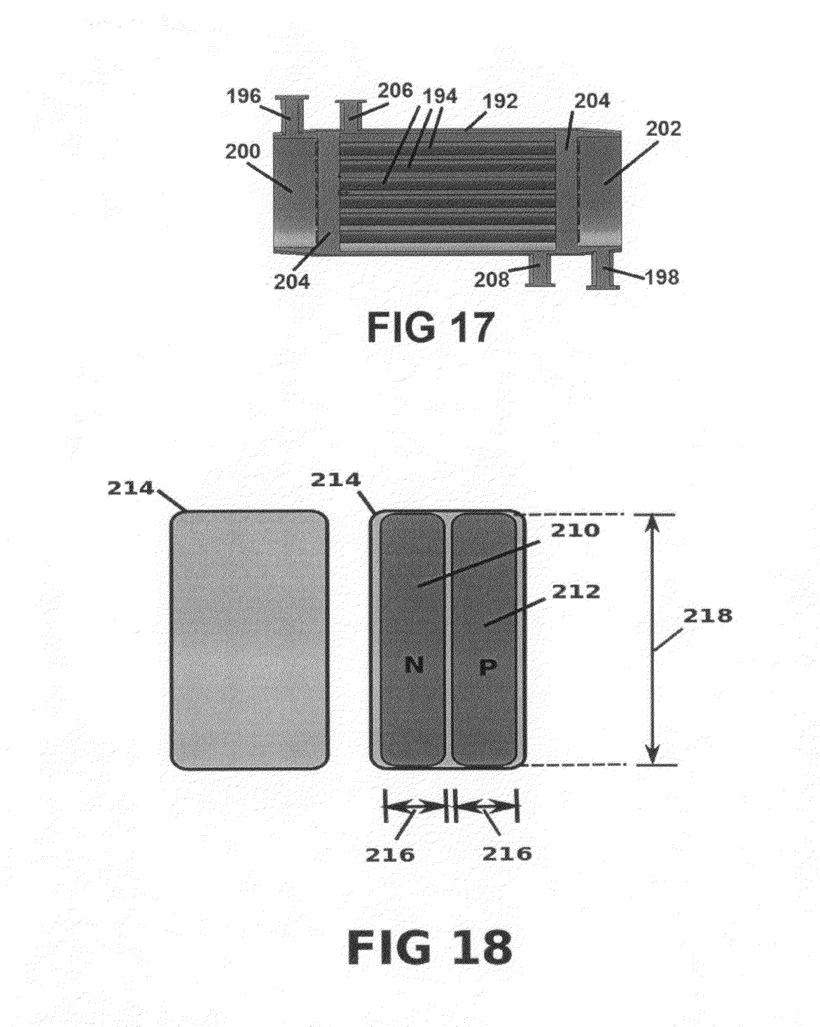

FIG. 17 depicts a shell and tube heat exchanger that is equipped with thermoelectric generation tubes. A shell and tube heat exchanger is a very common heat exchanger design. In may be considered a nested multi-tube system with the shell 192 being a large tube, inside of which are one or more parallel smaller tubes 194. Fluid at one temperature is introduced into the shell 192 at an inlet 206. The fluid is circulated around tubes 194 that carry a different fluid. There is no intermixing of the two fluids. The shell 192 can contain one or many tubes 194. When there is a single inside tube, the design is often called a double pipe heat exchanger. Fluid is introduced into the tubes 194 through a tube inlet 196 where the fluid goes into an inlet plenum 200. From the inlet plenum 200, the fluid flows in parallel through tubes 194 to an outlet plenum 202 and then to a tube outlet 198. When the tubes 194 are designed to be thermoelectric generator tubes, electrical power can be produced as a byproduct of heat transfer between the fluid in the tubes 194 and the fluid in the shell 192. For the purposes of this discussion, we assume that the temperature of the fluid entering the tube inlet 196 is higher than that entering the shell inlet 206, in which case heat energy flux flows from the inside of tubes 194 through a thermoelectric material and into the fluid in the shell 192, ultimately causing the fluid at the tube outlet 198 to have a temperature that is lower than the fluid at the tube inlet 196, and the fluid at the shell outlet 208 having a temperature that is higher than the fluid at the shell inlet 206.

Tube sheets 204 support the thermoelectric tubes 194 and serve to provide a seal that prevents fluid leakage from plenums 200, 202 into the shell 192. Electrical conductors coming from the thermoelectric tubes 194 can be combined at the tube sheets 204 and routed out of the shell 192 to provide electrical power generation as a byproduct of heat exchange.

Although the focus of the discussion has been directed at the construction of thermoelectric generation tubes using tublets, highlighting the advantages for volume production and for reducing thermal and electrical parasitics, the approach has similar advantages for thermoelectric heat pumping. By applying electrical power to the thermoelectric tubes 194, heat flow can be reversed and a shell and tube heat exchanger can be used as part of a system that reduces the temperature of the cooler fluid while increasing the temperature of the warmer fluid.

FIG. 18 depicts a flat plate thermoelectric base element which implements a thermoelectric couple. This is built by applying a layer of n-type thermoelectric material 210 and a layer of p-type thermoelectric material 212 to a flat, electrically conductive and thermally conductive substrate 214. The thermoelectric materials 210 and 212 may be applied to the substrate 214 in any of a number of ways including spraycasting or other deposition techniques that can accomplish a good mechanical and electrical bond at the interface between thermoelectric and substrate. The FIG. 18 depiction assumes that the n-type thermoelectric layer 210 is applied with the same width, length and thickness as the p-type thermoelectric layer 212. If the n-type thermoelectric material and the p-type thermoelectric material have significantly different material property values, σ, κ, and |S|, then it may be desirable to have different dimensions in order to optimize performance. The FIG. 18 embodiment serves as the base element from which thermoelectric devices can be built having many series connected thermoelectric couples, much as the thermoelectric tublet served as a base element for tubular thermoelectric generators. By comparing FIG. 18 to the thermoelectric dimensions depicted in FIG. 3, the thickness of the thermoelectric coating is L₁, the length L₂ of both thermoelements in FIG. 18 is 216, and the L₄ dimension is 218. When the flat plate thermoelectric base element is assembled into a composite device, the dimension 218 corresponds to the direction that is perpendicular to both the electrical current flow and the heat energy flux flow. As such, the amount of power that is produced is directly proportional to the dimension 218.

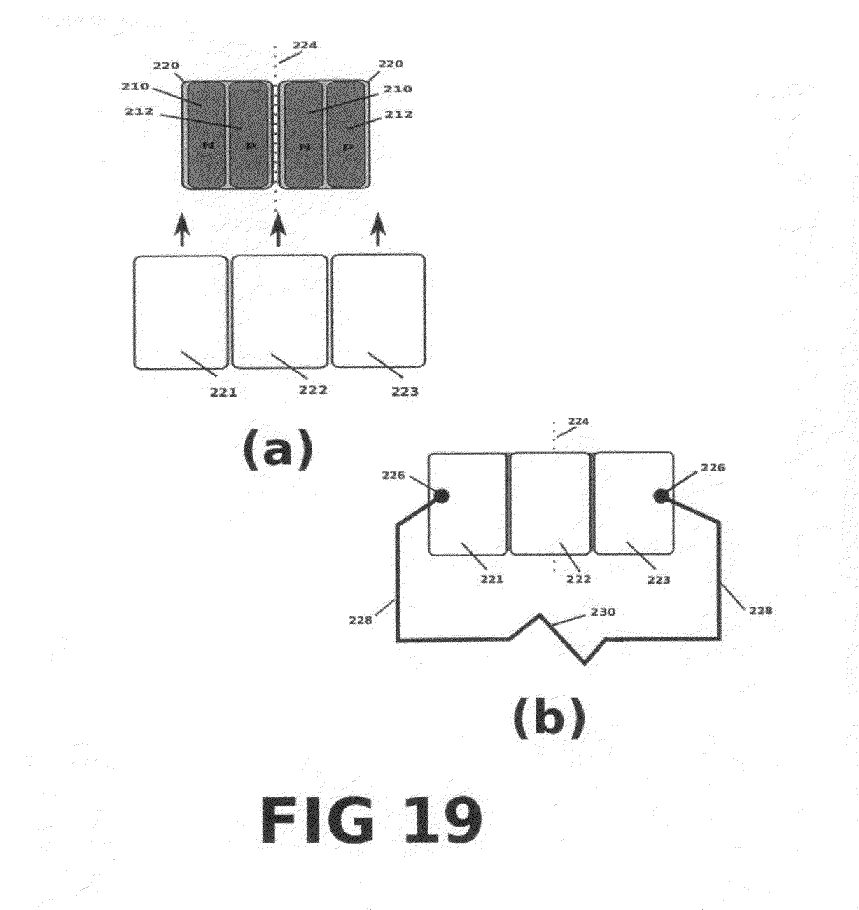

FIG. 19(a) depicts the construction of a two-couple (four thermoelement) flat plate thermoelectric device. Two single flat plate base elements are placed side by side with a gap 224 in the middle. Each of these base elements are constructed by applying a layer of n-type thermoelectric 210 next to a layer of p-type thermoelectric 212 on top of a bottom substrate 220. In order to complete the thermoelectric circuit, a top electrical conductor must be applied. This may be done by a deposition process—applying a coating of electrical conductor directly onto thermoelements to serve as the completion elements that establish a series electrical connection of multiple base elements. It can be accomplished by attaching an electrically conductive substrate onto the top of the base elements using a solder or other electrical attachment means, in which case the electrically conductive substrates serve as the completion elements that establish the series electrical connection. In FIG. 19(a), the top substrate is depicted in three parts, 221, 222 and 223. When the top substrates 221, 222 and 223 are placed over and electrically connected to the thermoelectric base elements, it yields a complete thermoelectric circuit as depicted in FIG. 19(b). When electrical connections 226 are attached to the left top substrate 221 and right top substrate 223, these serve as attachment points for electrical conductors 228 that connect to an electrical load 230. Heat energy flux flowing into or out of the device in a direction that is “into the page” will cause electrical energy to be delivered to the load 230. It may be desirable to apply dielectric or protective coatings to all or selected portions of the thermoelectric circuit in order to protect it against contaminants or electrical leakages between elements. Such coatings are not depicted in FIG. 19(b) and their use will be optional, depending upon the application. Using an approach similar to that depicted in FIG. 19, the construction of an N-couple generator requires N base elements and N+1 completion elements.

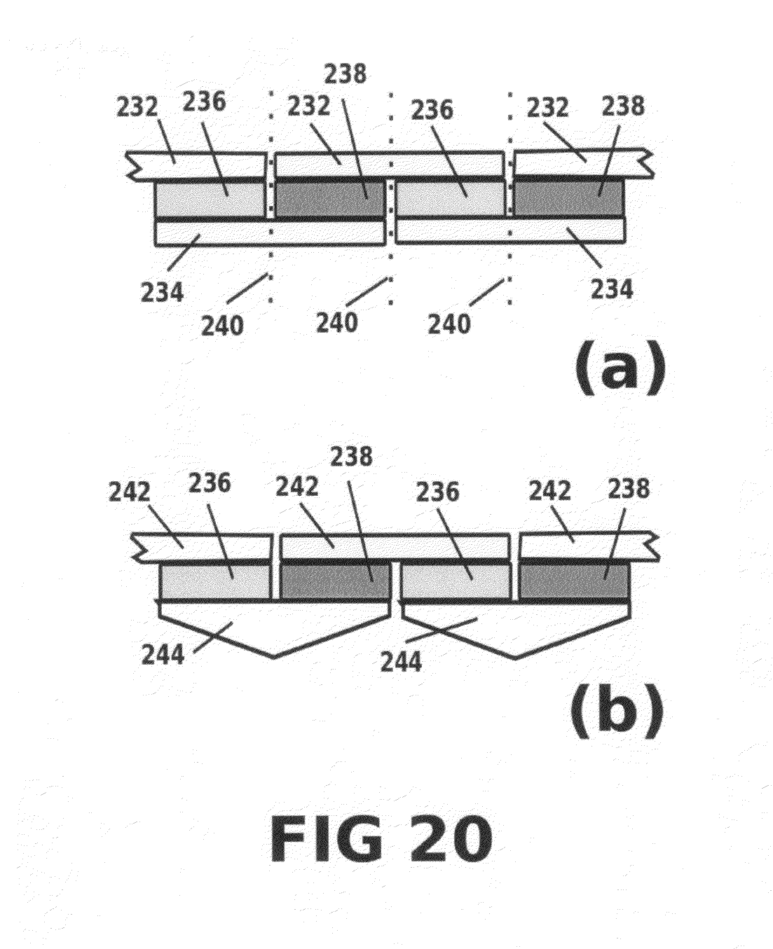

FIG. 20(a) depicts a side view of the connection of two flat-plate thermoelectric base elements. The top electrical conductors 232 and bottom electrical conductors 234 are depicted as having a uniform thickness as they would have if they were punched out of a flat sheet of material. As described previously, one advantage to using the electrical conductors as structural support for the thermoelements is that the number of electrical and thermal interfaces is reduced as are the accompanying parasitic losses. The regions 240 between thermoelements represent candidate places in which a bend or fold can take place, without applying mechanical stress to the active thermoelements 236,238. This allows the thermoelectric generator to be configured in a “fanfold” type of topology whereby the thermoelements can be configured into fins. FIG. 20(b) depicts an alternative configuration wherein the bottom electrical conductors 244 are not rectangular but are designed to be thicker in the regions between adjacent regions of thermoelectric 236 and 238. Similar to the discussion in conjunction with FIG. 16, a thicker conductor means reduced electrical conductivity and thus reduced electrical parasitics. In particular the electrical current flow between two adjacent thermoelements is highest across the attachment points between these thermoelements, so, it is advantageous to have the greatest cross-sectional surface area in this region. Furthermore, the increased perimeter on the conductor results in an increased area exposure to fluid flow in a direction that is normal (or “into the page”) relative to the illustrated cross-section. An advantage to this fabrication approach using flat plate base elements is that with two basic building blocks, namely the flat plate elements with thermoelectric coating and the conductor used to complete the circuit, thermoelectric generators of any arbitrary number of elements can be fabricated. Manufacturing requires simply these two basic building blocks to build a wide variety of configurations. This allows custom production equipment to be built that is very specialized, leading to low production cost. Since the flat thermoelectric generators can be configured as tubes, as described in the following figure, there is a great versatility in deployment.

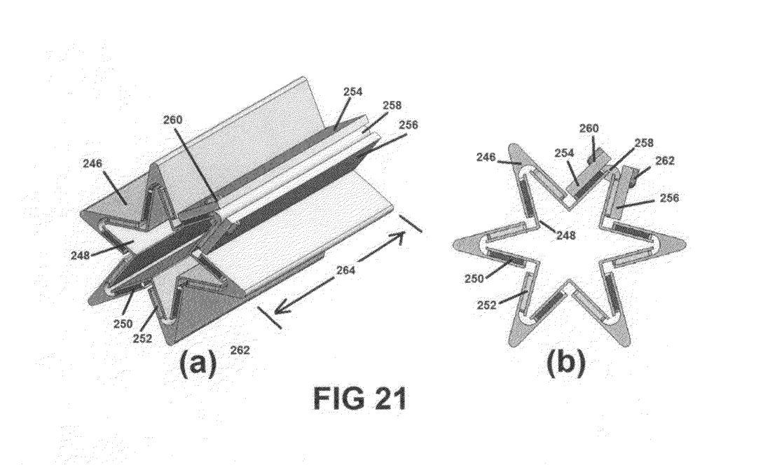

FIG. 21(a) illustrates the connection of multiple flat-plate base elements and multiple completion elements to form a tubular thermoelectric device. This embodiment is a “fanfold” type of design, wherein folds are made on each outside conductor 246 and each inside conductor 248. In the FIG. 21 embodiment, the base elements are folded in a “vee” of approximately 90 degrees and the completion elements are folded in a vee of approximately 60 degrees. The longitudinal creases (folds) serve to increase the surface area to a fluid on the inside and increases the surface area to a fluid on the outside, functioning to improve thermal transfer between fluids. Sandwiched between inside conductors 248 and outside conductors 246 are n-type thermoelements 252 and p-type thermoelements 250 and the entire arrangement comprises a pi topology. In thermoelectric generation, the heat flows from inside/outside the tube to the outside/inside. In thermoelectric heat pumping, the heat is moved from the inside (or outside) of the tube to the outside (or inside) of the tube. The tube walls, consisting of the folded flat-plate base elements and completion elements, serve a double duty of isolating the fluids and carrying out a thermoelectric function.

In order to close the tube, an electrically insulating seal 258 is used which runs longitudinally along the tube. This seal could be ceramic, organic or fiber based and serves two roles. First, it electrically isolates the two end conductors 254, 256. Second, it seals the tube, making it fluid tight for leakage between inside and outside. End conductors 254 and 256 are the electrical attachment means for the tube to the outside world, either an electrical load (when the tube is used for generation) or a power source (when the tube is used for heat pumping). End conductors 254 and 256 may be designed to be thicker than the nominal thickness of the outside conductors 246, to allow them to source electrical current to electrical connectors 260 and 262 without introducing excessive electrical parasitic resistance. The tube in FIG. 21(a) has an arbitrary length 264, corresponding to the L₄ dimension described earlier. In all of the inside conductors 248 and outside conductors 246, this dimension is perpendicular to both heat flow and electrical flow and as such, there is no penalty in terms of additional parasitics, for using a long dimension. However, for the end conductors 254 and 256, where the electrical current flow entering/exiting the tubular thermoelectric device is parallel to the L₄ dimension 264. it may be advantageous to have additional thickness as the full current will be delivered through parts of the cross-sections of 254 and 256. For a given temperature difference between the inside and the outside of the tubular thermoelectric device in FIG. 21(a), the generated voltage will be proportional to the number of series connected thermoelements and the generated current will be proportional to the length of the tube 264.

FIG. 21(b) shows a cross-section of the tubular thermoelectric device. This perspective highlights the fact that with this fanfold design, internal flow has contact with more of the wall (more cross-sectional perimeter) than it would contact in a cylindrical tube having the same internal cross-sectional area. The result is that there is more surface area available for the transmission of heat energy flux from interior to exterior. One of the advantages of using the fanfold design is that a heat exchanger wall that has thermoelectric elements in series between an inner wall and an outer wall, will necessarily introduce more thermal resistance to heat flow from inside fluid to outside fluid as contrasted with a traditional heat exchanger wall with no thermoelectrics. The use of the fanfold design helps to offset that increase because the additional contact area with internal and external fluids represents a reduction in thermal resistance (or equivalently an increase in thermal conductance) relative to a circular cross-section.

Although most of the previous discussion has focused on thermoelectric generation, the issues that detract from thermoelectric generation performance have a similar impact on thermoelectric heat pumping performance and so the geometric and dimensional guidelines for reducing electrical and thermal parasitics in generators apply equally well for heat pumping applications. For example, by applying electrical power between end conductors 260 and 262, the tubular thermoelectric device in FIG. 21 can be used to cool an internal fluid by pumping heat through the tube walls from the inside to an outside fluid. In this way, the invention has refrigeration applications.

Although the invention has been described in detail with particular references to these preferred embodiments, other embodiments can achieve the same results. Variations and modifications of the present invention will be obvious to those skilled in the art and it is intended to cover in the appended claims all such modifications and equivalents.

1. A multi-couple thermoelectric device comprising
a) two or more base elements each of which consists of an electrically conductive substrate having a coating of n-type thermoelectric material and a coating of p-type thermoelectric material; and
b) a number of conductive completion elements equal to the number of base elements plus one;
wherein said conductive completion elements complete the series electrical connection of said base elements resulting in the reduction of electrical and thermal parasitics by using said conductive substrate and said conductive completion elements for the multiple function of structural support, thermal conduction and electrical conduction.

2. The multi-couple thermoelectric device of claim 1 wherein said thermoelectric device is a thermoelectric generator.

3. The multi-couple thermoelectric device of claim 1 wherein said thermoelectric device is a thermoelectric heat pump.

4. The multi-couple thermoelectric device of claim 1 wherein said base elements and said completion elements are tubes.

5. The multi-couple thermoelectric device of claim 1 where said conductive completion elements have fins.

6. The multi-couple thermoelectric device of claim 1 where said conductive substrate has fins.

7. The multi-couple thermoelectric device of claim 4 wherein spacers are placed between each pair of said base elements, said spacers serving to create fluid turbulence inside said base element, thereby improving heat transfer to said substrate.

8. The multi-couple thermoelectric device of claim 5 wherein said fins serve to increase electrical conductivity in said series electrical connection and also increase the thermal conductivity to a thermal reservoir.

9. The multi-couple thermoelectric device of claim 6 wherein said fins serve to increase electrical conductivity in said series electrical connection and also increase the thermal conductivity to a thermal reservoir.

10. The multi-couple thermoelectric device of claim 1 wherein said conductive substrates are configured in a vee-shape and are connected by said conductive completion elements in such a way as to form a fanfold pipe with an insulating seam that seals said fanfold pipe so that it can be used to separate an internal fluid from an external fluid.

11. The multi-couple device of claim 10 wherein said vee-shape serves to increase the contact area to said internal fluid and to said external fluid.

12. A method for constructing a thermoelectric device comprising:
a. applying to each of two or more electrically and thermally conductive substrates one region of n-type thermoelectric material and one region of p-type thermoelectric material;
b. arranging said substrates in a positionally adjacent manner so that they relatively close but are not making electrical contact and in a way that no two regions of like thermoelectric material are next to one another; and
c. connecting an electrically and thermally conductive completion element on top of said regions of n-type thermoelectric material and p-type thermoelectric material on adjacent substrates in a manner to complete a series thermoelectric circuit.

13. The method of claim 12 wherein said region of n-type thermoelectric material and said region of p-type thermoelectric material are applied using a spray coat technique.

14. The method of claim 12 wherein said completion element between said adjacent substrates is applied using a spray coat technique.

15. The method of claim 12 wherein said completion element between said adjacent substrates is applied using a solder connection.

16. The method of claim 12 wherein said substrates and said completion elements serve a multiple role as electrical conductor, thermal conductor and mechanical support.
